(19) United States
(12) Patent Application Publication
(10) Pub. No.: US 2025/0040140 A1
(43) Pub. Date: Jan. 30, 2025

(54) SEMICONDUCTOR MEMORY DEVICE

(71) Applicant: Samsung Electronics Co., Ltd., Suwon-si (KR)

(72) Inventors: Ju Seong MIN, Suwon-si (KR); Jun Gyeom KIM, Suwon-si (KR); Hyun Min KIM, Suwon-si (KR); Kang-Oh YUN, Suwon-si (KR); Taek Kyu YOON, Suwon-si (KR); Dong Jin LEE, Suwon-si (KR); Jae Duk LEE, Suwon-si (KR); Jee Hoon HAN, Suwon-si (KR)

(73) Assignee: Samsung Electronics Co., Ltd., Suwon-si (KR)

(21) Appl. No.: 18/603,505

(22) Filed: Mar. 13, 2024

(30) Foreign Application Priority Data
Jul. 25, 2023 (KR) 10-2023-0096641

(51) Int. Cl. H10B 43/40; G11C 5/06; G11C 16/04; H01L 25/065; H10B 43/27; H10B 43/35; H10B 80/00

(52) U.S. Cl. CPC H10B 43/40; G11C 5/063; G11C 16/0483; H01L 25/0652; H10B 43/27; H10B 43/35; H10B 80/00; H01L 2225/06506

(57) ABSTRACT

A semiconductor memory device comprises a cell structure and a peripheral circuit structure electrically connected to the cell structure. The peripheral circuit structure comprises an active region, a first gate structure comprising a first gate insulating layer intersecting the active region and in contact with the active region, a second gate structure comprising a second gate insulating layer spaced apart from the first gate structure, and in contact with the active region, and a source/drain region between the first gate structure and the second gate structure. A thickness of the first gate insulating layer is less than a thickness of the second gate insulating layer. The source/drain region comprises a first region adjacent to the first gate structure and a second region adjacent to the second gate structure. A depth of the first region is equal to a depth of the second region.

### CROSS-REFERENCE TO RELATED APPLICATION

This application claims priority from Korean Patent/Application No. 10-2023-0096641 filed on Jul. 25, 2023 in the Korean Intellectual Property Office, and all the benefits accruing therefrom under 35 U.S.C. 119, the contents of which in its entirety are herein incorporated by reference.

### BACKGROUND

Various example embodiments relate to a semiconductor memory device.

In order to satisfy or help satisfy consumer demands for superior performance and/or inexpensive prices, it is desirable to increase the integration density of semiconductor memory devices. In a semiconductor memory device, since the integration density of the semiconductor memory device may be an important factor in determining the price of a product, an increased integration density is particularly required or desirable.

Meanwhile, regarding the structure of a transistor that controls an operation of a memory cell, research on a process for implementing one or more transistors is being conducted, where the transistors have gate insulating layers of different thicknesses on one active region.

### SUMMARY

Various example embodiments provide a semiconductor memory device with improved performance and reliability.

However, inventive concepts are not restricted to the one set forth herein. The above and other aspects of inventive concepts will become more apparent to one of ordinary skill in the art to which inventive concepts pertains by referencing the detailed description of various example embodiments below.

According to some example embodiments, there is provided a semiconductor memory device comprising a cell structure and a peripheral circuit structure electrically connected to the cell structure. The cell structure comprises, a plurality of gate electrodes extending in a first direction and spaced apart in a second direction, a channel structure penetrating the plurality of gate electrodes in the second direction, and a bit line connected to the channel structure and extending in a third direction. The peripheral circuit structure comprises an active region, a first gate structure comprising a first gate insulating layer intersecting the active region and in contact with the active region, a second gate structure comprising a second gate insulating layer spaced apart from the first gate structure, and in contact with the active region, and a source/drain region in the active region between the first gate structure and the second gate structure. A thickness of the first gate insulating layer is less than a thickness of the second gate insulating layer. The source/drain region comprises a first region adjacent to the first gate structure and a second region adjacent to the second gate structure. A depth of the first region is equal to a depth of the second region.

Alternatively or additionally according to various example embodiments, there is provided a semiconductor memory device comprising first and second active regions that are defined by an element isolation layer, a first gate structure comprising a first gate insulating layer intersecting the first active region, and in contact with the first active region, a second gate structure comprising a second gate insulating layer extending parallel to the first gate structure, and in contact with the first active region, and a first source/drain region in the first active region and between the first gate structure and the second gate structure, a third gate structure comprising a third gate insulating layer intersecting the second active region, and in contact with the second active region, and a second source/drain region on at least one side of the third gate structure in the second active region. A thickness of the first gate insulating layer is less than a thickness of the second gate insulating layer, wherein the first source/drain region comprises a first region adjacent to the first gate structure and a second region adjacent to the second gate structure. A depth of the first region is equal to a depth of the second region. A top surface of the first region is below a top surface of the second source/drain region.

Alternatively or additionally according to various example embodiments, there is provided a semiconductor memory device comprising a cell structure and a peripheral circuit structure electrically connected to the cell structure. The cell structure comprises a plurality of gate electrodes extending in a first direction and spaced apart in a second direction, a channel structure penetrating the plurality of gate electrodes in the second direction, and a bit line connected to the channel structure, and extending in a third direction. The peripheral circuit structure comprises first and second active regions that are defined by an element isolation layer, a first gate structure comprising a first gate insulating layer intersecting the first active region, and in contact with the first active region, a second gate structure comprising a second gate insulating layer extending parallel to the first gate structure, and in contact with the first active region, a first source/drain region in the first active region and between the first gate structure and the second gate structure, a third gate structure comprising a third gate insulating layer intersecting the second active region, and in contact with the second active region, and a second source/drain region in the second active region and on at least one side of the third gate structure. A thickness of the first gate insulating layer is less than a thickness of the second gate insulating layer. The first source/drain region comprises a first region adjacent to the first gate structure, and a second region adjacent to the second gate structure. A top surface of the first region above a top surface of the second region, but below a top surface of the second source/drain region. A depth of the first region is equal to a depth of the second region.

### BRIEF DESCRIPTION OF THE DRAWINGS

The above and other aspects and features of the present disclosure will become more apparent by describing in detail example embodiments thereof with reference to the attached drawings, in which:

FIG. 1 is an example block diagram explaining a semiconductor memory device according to some example embodiments.

FIG. 2 is an example circuit diagram explaining a semiconductor memory device according to some example embodiments.

FIG. 3 is an example cross-sectional view of a semiconductor memory device according to some example embodiments.

FIG. 4 is an enlarged view of region R1 of FIG. 3.

FIG. 5 is an enlarged view of region R2 of FIG. 3.

FIGS. 6 to 9 are diagrams explaining region R2 of FIG. 3 according to some other embodiments.

FIG. 10 is an enlarged view of region R3 of FIG. 3.

FIGS. 11 and 12 are diagrams explaining region R3 of FIG. 3 according to some other embodiments.

FIG. 13 is an enlarged view of region R4 of FIG. 3.

FIG. 14 is a cross-sectional view of a semiconductor memory device according to some other embodiments.

FIGS. 15 to 20 are views illustrating intermediate steps for explaining a method for fabricating a semiconductor memory device according to some example embodiments.

FIG. 21 is an example block diagram illustrating an electronic system according to some example embodiments.

FIG. 22 is an example perspective view illustrating an electronic system according to some example embodiments.

FIG. 23 is a schematic cross-sectional view taken along line I-I′ of FIG. 22.

### DETAILED DESCRIPTION OF VARIOUS EXAMPLE EMBODIMENTS

Although the terms first, second, etc. may be used herein to describe various elements or components, these elements or components should not be limited by these terms. These terms are used to distinguish one element or component from another element or component. Thus, a first element or component discussed below could be termed a second element or component without departing from the teachings of the present disclosure.

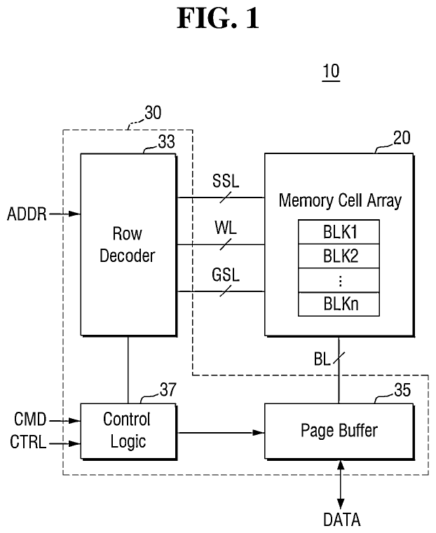

FIG. 1 is an example block diagram explaining a semiconductor memory device according to some example embodiments.

Referring to FIG. 1, a semiconductor memory device 10 according to various example embodiments includes a memory cell array 20 and a peripheral circuit 30.

The memory cell array 20 may include a plurality of memory cell blocks BLK1 to BLKn. Each of the memory cell blocks BLK1 to BLKn may include a plurality of memory cells—e.g., the same or a different number of memory cells. The memory cell array 20 may be connected to the peripheral circuit 30 through bit lines BL, word lines WL, at least one of string select lines SSL, and at least one of ground select lines GSL. Specifically, the memory cell blocks BLK1 to BLKn may be connected to a row decoder 33 through the word lines WL, the string select lines SSL, and the ground select lines GSL. Further, the memory cell blocks BLK1 to BLKn may be connected to a page buffer 35 through the bit lines BL.

The peripheral circuit 30 may receive one or more of an address ADDR, a command CMD, and a control signal CTRL from the outside of the semiconductor memory device 10, and may transmit and receive data DATA to and from an external device of the semiconductor memory device 10. The peripheral circuit 30 may include a control logic 37, the row decoder 33 and the page buffer 35. Although not shown, the peripheral circuit 30 may further include various sub-circuits such as an input/output circuit, a voltage generation circuit for generating various voltages required or used for the operation of the semiconductor memory device 10, and an error correction circuit for detecting and/or correcting an error of data DATA read from the memory cell array 20.

The control logic 37 may be connected to the row decoder 33, the input/output circuit and the voltage generation circuit. The control logic 37 may control an overall operation of the semiconductor memory device 10. The control logic 37 may generate various internal control signals used in the semiconductor memory device 10 in response to the control signal CTRL. For example, the control logic 37 may adjust a voltage level provided to the word lines WL and/or the bit lines BL during the execution of a memory operation such as a program operation and/or an erase operation.

The row decoder 33 may select at least one of the plurality of memory cell blocks BLK1 to BLKn in response to the address ADDR. The row decoder 33 may select at least one of the word lines WL, at least one of the string select lines SSL and at least one of the ground select lines GSL for the selected at least one of the memory cell blocks BLK1 to BLKn. The row decoder 33 may transmit a voltage for performing a memory operation to the word lines WL of the selected at least one of the memory cell blocks BLK1 to BLKn.

The page buffer 35 may be connected to the memory cell array 20 through the bit lines BL. The page buffer 35 may operate as a writer driver and/or as a sense amplifier. For example, during the program operation, the page buffer 35 may operate as a write driver to apply, to the bit lines BL, a voltage corresponding to the data DATA intended to be stored in the memory cell array 20. On the other hand, during the read operation, the page buffer 35 may operate as a sense amplifier to sense the data DATA stored in the memory cell array 20.

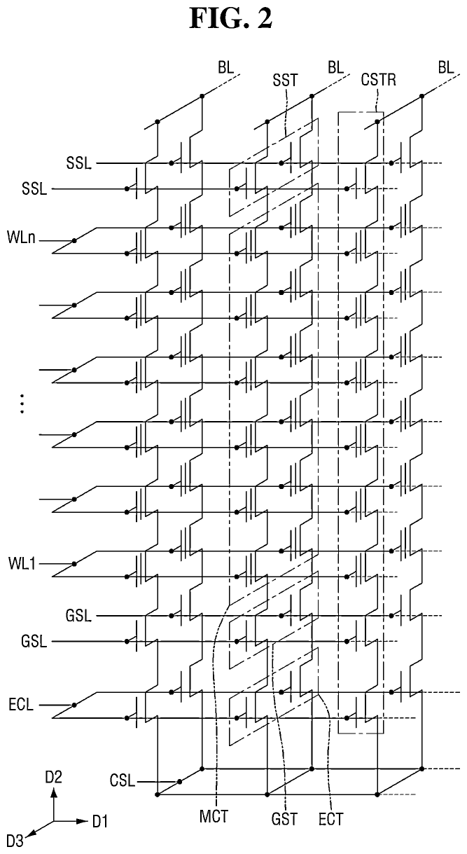

FIG. 2 is an example circuit diagram explaining a semiconductor memory device according to some example embodiments.

Referring to FIG. 2, a memory cell array (e.g., ‘20’ in FIG. 1) of the semiconductor memory device according to some example embodiments may include a common source line CSL, a plurality of bit lines BL, and a plurality of cell strings CSTR.

The common source line CSL may extend in a first direction D1. In some example embodiments, the plurality of common source lines CSL may be arranged two-dimensionally. For example, the plurality of common source lines CSL may extend in the first direction D1 while being spaced apart from each other. The same voltage may be applied to the common source lines CSL. Alternatively, different voltages may be applied to the common source lines CSL to be controlled separately.

The plurality of bit lines BL may be two-dimensionally arranged. For example, the bit lines BL may extend in a third direction D3 crossing the first direction D1 while being spaced apart from each other. The plurality of cell strings CSTR may be connected in parallel to each of the bit lines BL. The cell strings CSTR may be commonly connected to the common source lines CSL. That is, the plurality of cell strings CSTR may be disposed between the bit lines BL and the common source lines CSL.

Each of the cell strings CSTR may include a ground select transistor GST connected to the common source line CSL, a string select transistor SST connected to the bit line BL, and a plurality of memory cell transistors MCT disposed between the ground select transistor GST and the string select transistor SST. Each of the memory cell transistors MCT may include a data storage element. The ground select transistor GST, the string select transistor SST, and the memory cell transistors MCT may be connected in series in a second direction D2. In the present specification, the first direction D1, the third direction D3, and the second direction D2 may be substantially perpendicular to each other.

The common source line CSL may be commonly connected to the sources of the ground select transistors GST. Further, a ground select line GSL, a plurality of word lines WL1 to WLn, and a string select line SSL may be disposed between the common source line CSL and the bit line BL. A number of word lines WL1 to WLn may be different from a number of blocks BL1 to BLn. The ground select line GSL may be used as a gate electrode of the ground select transistor GST. The word lines WL1 to WLn may be used as or may correspond to gate electrodes of the memory cell transistors MCT. The string select line SSL may be used as or may correspond to a gate electrode of the string select transistor SST.

In some example embodiments, an erase control transistor ECT may be disposed between the common source line CSL and the ground select transistor GST. The common source line CSL may be commonly connected to sources of the erase control transistors ECT. An erase control line ECL may be disposed between the common source line CSL and the ground select line GSL. The erase control line ECL may be used as a gate electrode of the erase control transistor ECT. The erase control transistors ECT may perform an erase operation of the memory cell array by generating a gate induced drain leakage (GIDL).

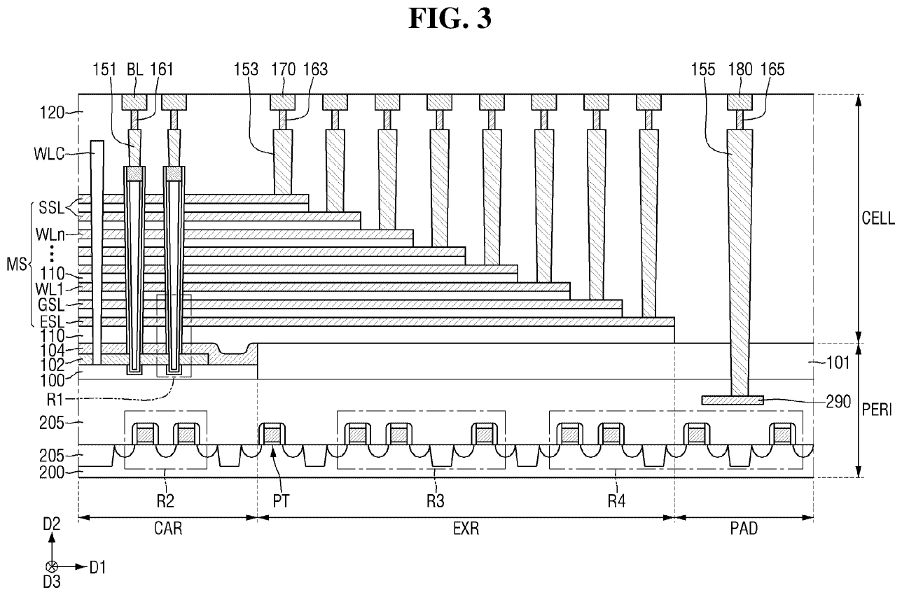

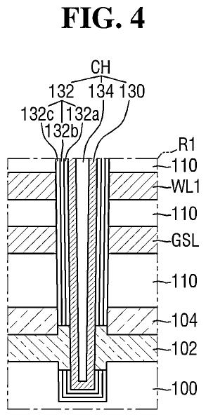

FIG. 3 is an example cross-sectional view of a semiconductor memory device according to some example embodiments. FIG. 4 is an enlarged view of region R1 of FIG. 3.

Referring to FIGS. 3 and 4, a semiconductor memory device according to some example embodiments includes a cell structure CELL and a peripheral circuit structure PERI.

In some example embodiments, the cell structure CELL may include a cell substrate 100, a mold structure MS, a cell interlayer insulating layer 120, a channel structure CH, a word line cutting structure WLC, the bit line BL, a plurality of cell contacts 153, and a through contact 155.

A semiconductor memory device according to various example embodiments may include a cell array region CAR, an extension region EXR, and a pad region PAD. Although the cell array region CAR, the extension region EXR, and the pad region PAD are illustrated as being connected to each other, the technical spirit of the present disclosure is not limited thereto.

A memory cell array (e.g., ‘20’ in FIG. 1) including a plurality of memory cells may be formed in the cell array region CAR. For example, the channel structure CH, the bit line BL, gate electrodes ECL, GSL, WL1 to WL1n, and SSL, and the like, which will be described later, may be disposed in the cell array region CAR.

The extension region EXR may be disposed around the cell array region CAR. The gate electrodes ECL, GSL, WL1 to WLn, and SSL, which will be described later, may be stacked in a stepwise manner in the extension region EXR. Further, the plurality of cell contacts 153 to be described layer, and the like may be disposed in the extension region EXR.

The pad region PAD may be disposed inside or outside the cell array region CAR and the extension region EXR. The through contact 155 to be described layer, and the like may be disposed in the pad region PAD.

A substrate may include the cell array region CAR, the extension region EXR, and the pad region PAD. The substrate may include the cell substrate 100 and an insulating pattern 101, but is not limited thereto.

The cell substrate 100 may include, for example, a semiconductor substrate such as one or more of a silicon substrate, a germanium substrate, or a silicon-germanium substrate. Alternatively, the cell substrate 100 may include a silicon-on-insulator (SOI) substrate and/or a germanium-on-insulator (GOI) substrate. In some example embodiments, the cell substrate 100 may include impurities. For example, the cell substrate 100 may include n-type impurities (e.g., phosphorus (P) and/or arsenic (As) and/or the like) and/or p-type impurities (e.g., boron (B) and/or the like).

The insulating pattern 101 may be provided in the extension region EXR and the pad region PAD. The insulating pattern 101 may include, for example, at least one of silicon oxide, silicon nitride, silicon oxynitride and silicon carbide, but is not limited thereto. Unlike the illustration, the insulating pattern 101 may be provided in the cell substrate 100.

The mold structure MS may be provided on the front surface (e.g., top surface) of the cell substrate 100. The mold structure MS may include the plurality of gate electrodes ECL, GSL, WL1 to WLn, and SSL and a plurality of mold insulating layers 110 which are alternately stacked on the cell substrate 100. The gate electrodes ECL, GSL, WL1 to WLn, and SSL and the mold insulating layers 110 may have a layered structure in which each of the gate electrodes ECL, GSL, WL1 to WLn, and SSL and each of the mold insulating layers 110 extend parallel to the top surface of the cell substrate 100. The gate electrodes ECL, GSL, WL1 to WLn, and SSL may be sequentially stacked on the cell substrate 100 while being spaced apart from each other by the mold insulating layers 110.

The gate electrodes ECL, GSL, WL1 to WLn, and SSL may be stacked in a stepwise manner, e.g., a staircase manner on the extension region EXR. For example, the gate electrodes ECL, GSL, WL1 to WLn, and SSL may extend to different lengths in the first direction D1 and have a stepped portion. In some example embodiments, the gate electrodes ECL, GSL, WL1 to WLn, and SSL may have a stepped portion in the third direction D3. Accordingly, each of the gate electrodes ECL, GSL, WL1 to WLn, and SSL may be exposed from the other gate electrodes. The exposed portions may refer to regions where the plurality of cell contacts 153 and the gate electrodes are in contact with each other.

In some example embodiments, the gate electrodes ECL, GSL, WL1 to WLn, and SSL may include the erase control line ECL, the ground select line GSL, and the plurality of word lines WL1 to WLn that are sequentially stacked on the cell substrate 100. In some example embodiments, the erase control line ECL may be omitted.

The mold insulating layers 110 may be stacked in a stepwise manner on the extension region EXR. For example, the mold insulating layers 110 may extend to different lengths in the first direction D1 and have a stepped portion. In some example embodiments, the mold insulating layers 110 may have a stepped portion in the third direction D3.

Each of the gate electrodes ECL, GSL, WL1 to WLn, and SSL may include, a conductive material, for example, metal such as one or more of tungsten (W), cobalt (Co), and nickel (Ni), or a semiconductor material such as silicon, but is not limited thereto. For example, each of the gate electrodes ECL, GSL, WL1 to WLn, and SSL may include tungsten (W). Unlike the illustration, the gate electrodes ECL, GSL, WL1 to WLn, and SSL may be multiple layers. For example, when the gate electrodes ECL, GSL, WL1 to WLn, and SSL are multiple layers, the gate electrodes ECL, GSL, WL1 to WLn, and SSL may include a gate electrode barrier layer and a gate electrode filling layer. The gate electrode barrier layer may include, for example, titanium nitride (TiN), and the gate electrode filling layer may include tungsten (W), but example embodiments are not limited thereto.

The mold insulating layer 110 may include an insulating material, for example, at least one of silicon oxide, silicon nitride, or silicon oxynitride, but is not limited thereto. For example, the mold insulating layer 110 may include silicon oxide.

The channel structure CH may be provided in the mold structure MS of the cell array region CAR. The channel structure CH may extend in a vertical direction (hereinafter, a second direction D2) crossing the top surface of the cell substrate 100, and may penetrate the mold structure MS and the gate electrodes ECL, GSL, WL1 to WLn, and SSL. For example, the channel structure CH may have a pillar shape (e.g., a cylindrical shape or a tapered cylindrical shape) extending in the second direction D2. Accordingly, the channel structure CH may intersect each of the gate electrodes ECL, GSL, WL1 to WLn, and SSL.

The channel structure CH may include a semiconductor pattern 130 and an information storage layer 132.

The semiconductor pattern 130 may extend in the second direction D2 to penetrate the mold structure MS. The semiconductor pattern 130 is shown only in a cup shape, but this is merely example. For example, the semiconductor pattern 130 may have various shapes such as a cylindrical shape, a rectangular tube shape, a prismatic shape, and a solid pillar shape. The semiconductor pattern 130 may include, for example, a semiconductor material such as monocrystalline silicon, polycrystalline silicon, organic semiconductor material, and carbon nanostructure, but is not limited thereto.

The information storage layer 132 may be interposed between the semiconductor pattern 130 and each of the gate electrodes ECL, GSL, WL1 to WLn, and SSL. For example, the information storage layer 132 may extend along an outer side surface of the semiconductor pattern 130. The information storage layer 132 may include, for example, at least one of silicon oxide, silicon nitride, silicon oxynitride, or a high dielectric constant material having a higher dielectric constant than silicon oxide. The high-k material may include, for example, at least one selected from the group consisting of aluminum oxide, hafnium oxide, lanthanum oxide, tantalum oxide, titanium oxide, lanthanum hafnium oxide, lanthanum aluminum oxide, dysprosium scandium oxide and a combination thereof.

In some example embodiments, the information storage layer 132 may be formed as multiple layers. For example, as shown in FIG. 4, the information storage layer 132 may include a tunnel insulating layer 132a, a charge storage layer 132b, and a blocking insulating layer 132c that are sequentially stacked on the outer surface of the semiconductor pattern 130.

The tunnel insulating layer 132a may include, for example, silicon oxide and/or a high-k material (e.g., aluminum oxide (Al₂O₃) and/or hafnium oxide (HfO₂)) having a higher dielectric constant than silicon oxide. The charge storage layer 132b may include, for example, silicon nitride. The blocking insulating layer 132c may include, for example, silicon oxide and/or a high-k material (e.g., aluminum oxide (Al₂O₃) and/or hafnium oxide (HfO₂)) having a higher dielectric constant than silicon oxide.

In some example embodiments, the channel structure CH may further include a filling pattern 134. The filling pattern 134 may be formed to fill an interior of the semiconductor pattern 130 having a cup shape. The filling pattern 134 may include an insulating material, e.g., silicon oxide, but is not limited thereto.

In some example embodiments, the channel structure CH may further include a channel pad 136. The channel pad 136 may be formed to be connected to the semiconductor pattern 130. For example, the channel pad 136 may be formed in the cell interlayer insulating layer 120 to be described later and connected to an upper portion of the semiconductor pattern 130. The channel pad 136 may include, for example, polysilicon doped with impurities, but is not limited thereto.

In some example embodiments, a source layer 102 and a source support layer 104 may be sequentially formed on the cell substrate 100. The source layer 102 and the source support layer 104 may be interposed between the cell substrate 100 and the mold structure MS. For example, the source layer 102 and the source support layer 104 may extend along the top surface of the cell substrate 100.

In some example embodiments, the source layer 102 may be formed to be connected to the semiconductor pattern 130 of the channel structure CH. For example, as shown in FIG. 4, the source layer 102 may penetrate the information storage layer 132 to be in contact with the semiconductor pattern 130. This source layer 102 may be provided as a common source line (e.g., ‘CSL’ in FIG. 2) of the semiconductor memory device. The source layer 102 may include, for example, impurity-doped polysilicon and/or metal, but is not limited thereto.

In some example embodiments, the channel structure CH may penetrate the source layer 102 and the source support layer 104. By way of example, a lower portion of the channel structure CH may penetrate the source layer 102 and the source support layer 104 and be buried in the cell substrate 100.

In some example embodiments, the source support layer 104 may be used as a support layer for preventing a mold stack from falling or collapsing in a replacement step for forming the source layer 102.

Although not shown, a base insulating layer may be interposed between the cell substrate 100 and the source layer 102. The base insulating layer may include, for example, at least one of silicon oxide, silicon nitride, or silicon oxynitride, but is not limited thereto.

In some example embodiments, the insulating pattern 101 may be formed in the extension region EXR and the pad region PAD. Although the top surface of the insulating pattern 101 is illustrated as being coplanar with the top surface of the source support layer 104, this is nothing more than an example. As another example, the top surface of the insulating pattern 101 may be higher than or above the top surface of the source support layer 104.

The word line cutting structure WLC may cut the mold structure MS. The mold structure MS may be cut by the word line cutting structure WLC to form a plurality of memory cell blocks (e.g., ‘BLK1 to BLKn’ in FIG. 1). For example, although not shown, two adjacent word line cutting structures WLC may define one memory cell block between them. The plurality of channel structures CH may be disposed in each of the memory cell blocks defined by the word line cutting structures WLC.

In some example embodiments, the word line cutting structure WLC may cut the source layer 102 and the source support layer 104. Although the bottom surface of the word line cutting structure WLC is illustrated as being coplanar with the bottom surface of the source layer 102, this is nothing more than an example. As another example, the bottom surface of the word line cutting structure WLC may be lower than the bottom surface of the source layer 102.

In some example embodiments, the word line cutting structure WLC may include an insulating material. For example, the insulating material may fill the word line cutting structure WLC. The insulating material may include, for example, at least one of silicon oxide, silicon nitride, or silicon oxynitride, but is not limited thereto.

Although not shown, a string isolation structure may be provided in the mold structure MS. The string isolation structure may cut the string select line SSL. Each of the memory cell blocks defined by word line cutting structures WLC may be divided by the string isolation structure to form a plurality of string regions. For example, the string isolation structure may define two string areas in one memory cell block.

The cell interlayer insulating layer 120 may be disposed on the mold structure MS. The cell interlayer insulating layer 120 may cover the plurality of channel structures CH, the plurality of cell contacts 153, and the through contact 155. The cell interlayer insulating layer 120 may include an oxide-based insulating material. The cell interlayer insulating layer 120 may include, for example, at least one of silicon oxide, silicon oxynitride, or a low-k material having a lower dielectric constant than silicon oxide, but is not limited thereto.

The bit line BL may be disposed on the substrate in the cell array region CAR. The bit line BL may be formed on the mold structure MS. The bit line BL may be or may correspond to a bit line BL (see FIG. 2) of a semiconductor memory device. The bit line BL may be disposed in the cell interlayer insulating layer 120. The bit line BL may extend in the third direction D3.

The bit line BL may be connected to the plurality of channel structures CH. As an example, first and second bit line contacts 151 and 161 connected to upper portions of the respective channel structures CH may be formed in the cell interlayer insulating layer 120. The first bit line contact 151 is disposed on the channel structure CH. The first bit line contact 151 may be connected to the channel pad 136. The second bit line contact 161 is disposed on the first bit line contact 151. The second bit line contact 161 may be connected to the bit line BL. The second bit line contact 161 may be provided between each bit line BL and the first bit line contact 151. The bit line BL may be electrically connected to the channel structures CH through the first and second bit line contacts 151 and 161.

The bit line BL may include a conductive material. For example, the bit line BL may include tungsten (W) and/or copper (Cu), but is not limited thereto.

The plurality of cell contacts 153 may be provided on the substrate in the extension region EXR. The plurality of cell contacts 153 may extend in the second direction D2 in the extension region EXR and penetrate the cell interlayer insulating layer 120. Each of the plurality of cell contacts 153 may be connected to one of the plurality of gate electrodes ECL, GSL, WL1 to WLn, and SSL. For example, each of the plurality of cell contacts 153 may land on the gate electrode disposed at the highest level among the plurality of gate electrodes ECL, GSL, WL1 to WLn, and SSL. In some example embodiments, each of the plurality of cell contacts 153 may be electrically connected to the gate electrode disposed at the highest level among the plurality of gate electrodes ECL, GSL, WL1 to WLn, and SSL.

The top surfaces of the plurality of cell contacts 153 may be all coplanar. In addition, the bottom surfaces of the plurality of cell contacts 153 may be all coplanar. However, example embodiments are not limited thereto.

A plurality of first metal patterns 170 may be disposed on the substrate in the extension region EXR. The plurality of first metal patterns 170 may be disposed on the mold structure MS. The plurality of first metal patterns 170 may be respectively connected to the plurality of cell contacts 153. For example, first via contacts 163 may be formed between the plurality of first metal patterns 170 and the cell contacts 153. The plurality of first metal patterns 170 may be electrically connected to the cell contacts 153 through the first via contacts 163.

The plurality of first metal patterns 170 may include a conductive material. For example, the plurality of first metal patterns 170 may include tungsten (W) and/or copper (Cu), but are not limited thereto.

The through contact 155 may be provided on the substrate in the pad region PAD. The through contact 155 may extend in the second direction D2 in the pad region PAD to penetrate the cell interlayer insulating layer 120. Also, the through contact 155 may also penetrate the insulating pattern 101. The through contact 155 may penetrate the insulating pattern 101 to be connected to a peripheral circuit element PT of the peripheral circuit structure PERI to be described later. The through contact 155 may be connected to, for example, a wiring pattern 290 of the peripheral circuit structure PERI.

A plurality of second metal patterns 180 may be disposed on the substrate in the pad region PAD. The plurality of second metal patterns 180 may be provided in the cell interlayer insulating layer 120. The plurality of second metal patterns 180 may be connected to the through contact 155. For example, a second via contact 165 may be formed between the plurality of second metal patterns 180 and the through contact 155. The plurality of second metal patterns 180 may be electrically connected to the through contact 155 through the second via contact 165.

The plurality of second metal patterns 180 may include a conductive material. For example, the plurality of second metal patterns 180 may include tungsten (W) and/or copper (Cu), but are not limited thereto.

In some example embodiments, the peripheral circuit structure PERI may include the peripheral circuit substrate or board 200 and the peripheral circuit element PT.

The peripheral circuit board 200 may be disposed under the cell substrate 100. For example, the top surface of the peripheral circuit board 200 may face the bottom surface of the cell substrate 100. The peripheral circuit board 200 may include, for example, a semiconductor substrate such as one or more of a silicon substrate, a germanium substrate, or a silicon-germanium substrate. Alternatively, the peripheral circuit board 200 may include a silicon-on-insulator (SOI) substrate and/or a germanium-on-insulator (GOI) substrate.

The peripheral circuit element PT may be formed on the peripheral circuit board 200. The peripheral circuit element PT may constitute or correspond to a peripheral circuit (e.g., ‘30’ in FIG. 1) that controls the operation of the semiconductor memory device. For example, the peripheral circuit element PT may include a control logic (e.g., ‘37’ in FIG. 1), a row decoder (e.g., ‘33’ in FIG. 1), and a page buffer (e.g., ‘35’ in FIG. 1). As an example, the peripheral circuit element PT may be a page buffer and may control the operation of the bit line BL, but example embodiments are not limited thereto.

In the following description, a surface of the peripheral circuit board 200, on which the peripheral circuit element PT is disposed, may be referred to as a front surface of the peripheral circuit board 200. On the contrary, a surface of the peripheral circuit board 200, which is opposite to the front surface of the peripheral circuit board 200, may be referred to as a rear surface of the peripheral circuit board 200.

The peripheral circuit element PT may include, for example, a transistor, but is not limited thereto. For example, the peripheral circuit element PT may include various active elements such as a transistor and/or a diode, as well as various passive elements such as one or more of a memristor, a capacitor, a resistor, and an inductor. Although FIG. 3 illustrates that the peripheral circuit element PT extends in the third direction D3, example embodiments are not limited thereto, and the peripheral circuit element PT may extend in the second direction D2.

In some example embodiments, the rear surface of the cell substrate 100 may face the front surface of the peripheral circuit board 200. For example, a peripheral circuit interlayer insulating layer 220 covering the peripheral circuit element PT may be formed on the front surface of the peripheral circuit board 200. The cell substrate 100 and/or the insulating pattern 101 may be stacked on the top surface of the peripheral circuit interlayer insulating layer 220.

The plurality of second metal patterns 180 may be connected to the peripheral circuit element PT through the through contact 155. For example, the wiring pattern 290 connected to the peripheral circuit element PT may be formed in the peripheral circuit interlayer insulating layer 220. The bit line BL, each of the gate electrodes ECL, GSL, WL1 to WLn, and SSL, and/or the source layer 102 may be electrically connected to the peripheral circuit element PT through the wiring pattern 290.

The peripheral circuit elements PT may be separated by a peripheral element isolation layer 205. For example, the peripheral element isolation layer 205 may be provided in the peripheral circuit board 200. The peripheral element isolation layer 205 may be or may include a shallow trench isolation (STI) layer. The peripheral element isolation layer 205 may define active regions of the peripheral circuit elements PT. The peripheral element isolation layer 205 may include an insulating material. The peripheral element isolation layer 205 may include, for example, at least one of silicon nitride, silicon oxide, or silicon oxynitride.

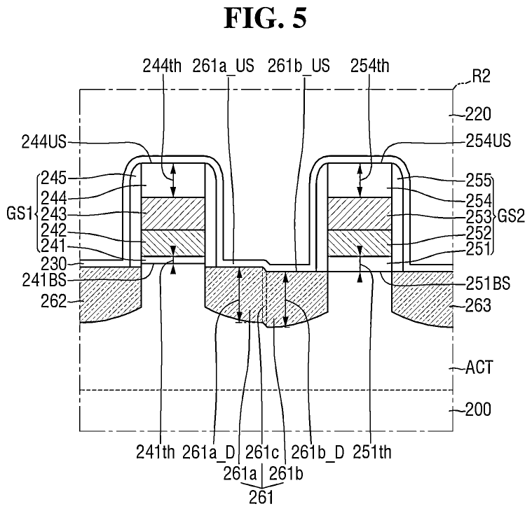

The peripheral circuit clement PT will be described in further detail with reference to FIGS. 5 to 14.

FIG. 5 is an enlarged view of region R2 of FIG. 3. Referring to FIG. 5, a semiconductor memory device according to various example embodiments may include an active region ACT, a first gate structure GS1, a second gate structure GS2, a first source/drain region 261, a second source/drain region 262, and a third source/drain region 263.

The active region ACT may be disposed on the peripheral circuit board 200. The active region ACT may be used as a channel of a transistor. The first gate structure GS1 and the second gate structure GS2 may be disposed on the active region ACT. That is, the first gate structure GS1 and the second gate structure GS2 may be disposed on the same active region ACT.

The first gate structure GS1 may be disposed on the active region ACT. The first gate structure GS1 may intersect the active region ACT. For example, assuming that the active region ACT extends in the X-axis direction, the first gate structure GS1 may extend in the Y-axis direction intersecting the X-axis direction.

The first gate structure GS1 may include a first gate insulating layer 241, a first lower gate pattern 242, a first upper gate pattern 243, a first gate capping layer 244, and a first gate spacer 245.

The first gate insulating layer 241, the first lower gate pattern 242, the first upper gate pattern 243, and the first gate capping layer 244 may be sequentially stacked on the active region ACT. For example, the first lower gate pattern 242 may be disposed on the first gate insulating layer 241. The first upper gate pattern 243 may be disposed on the first lower gate pattern 242. The first gate capping layer 244 may be disposed on the first upper gate pattern 243. The first gate insulating layer 241 may be in contact with at least a part of the active region ACT.

The first gate spacer 245 may extend along the sidewalls of the first gate insulating layer 241, the first lower gate pattern 242, the first upper gate pattern 243, and the first gate capping layer 244.

A second gate insulating layer 251, a second lower gate pattern 252, a second upper gate pattern 253, and a second gate capping layer 254 may be sequentially stacked on the active region ACT. For example, the second lower gate pattern 252 may be disposed on the second gate insulating layer 251. The second upper gate pattern 253 may be disposed on the second lower gate pattern 252. The second gate capping layer 254 may be disposed on the second upper gate pattern 253. The second gate insulating layer 251 may be in contact with at least a part of the active region ACT. The second gate insulating layer 251 may not be disposed on the first source/drain region 261 and the third source/drain region 263.

A second gate spacer 255 may extend along the sidewalls of the second gate insulating layer 251, the second lower gate pattern 252, the second upper gate pattern 253, and the second gate capping layer 254.

Each of the first gate insulating layer 241 and the second gate insulating layer 251 may concurrently or independently include, for example, at least one of silicon oxide, silicon oxynitride, silicon nitride, or a high-k material having a higher dielectric constant greater than silicon oxide. The high-k material may include, for example, at least one selected from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. As an example, each of the first gate insulating layer 241 and the second gate insulating layer 251 may be formed of a silicon oxide layer.

Each of the first lower gate pattern 242 and the second lower gate pattern 252 may include, for example, a polysilicon layer such as a doped polysilicon layer, but is not limited thereto.

Each of the first upper gate pattern 243 and the second upper gate pattern 253 may include a metallic material. For example, each of the first upper gate pattern 243 and the second upper gate pattern 253 may include tungsten (W), but is not limited thereto.

Each of the first gate capping layer 244 and the second gate capping layer 254 may be formed of, for example, a silicon nitride layer, and in some example embodiments, the first gate capping layer 244 may be formed at the same time and integrated with the second gate capping layer 254, but is not limited thereto.

The first gate spacer 245 and the second gate spacer 255 may be formed of, for example, and in some example embodiments, the first gate spacer 254 may be formed at the same time and integrated with the second gate spacer 255; however, example embodiments are not limited thereto. In some example embodiments, either or both of the first gate spacer 245 and the second gate spacer 255 may include a silicon oxide layer, but are not limited to them.

In some example embodiments, a thickness 241th of the first gate insulating layer 241 in the vertical direction is smaller than, e.g., thinner by a number of angstroms such as by between 5 angstroms and 50 angstroms, as a thickness 251th of the second gate insulating layer 251 in the vertical direction.

In this case, the top surface of the first gate insulating layer 241 and the top surface of the second gate insulating layer 251 may be placed on the same plane. However, a bottom surface 241BS of the first gate insulating layer 241 is not placed on the same plane as a bottom surface 251BS of the second gate insulating layer 251. For example, the vertical level of the bottom surface 241BS of the first gate insulating layer 241 may be higher than the vertical level of the bottom surface 251BS of the second gate insulating layer 251. In some example embodiments, the height from the top surface of the peripheral circuit board 200 to the bottom surface 241BS of the first gate insulating layer 241 is larger than the height from the top surface of the peripheral circuit board 200 to the bottom surface 251BS of the second gate insulating layer 251.

In a semiconductor memory device according to some example embodiments, since the thickness 241th of the first gate insulating layer 241 in the vertical direction is smaller than the thickness 251th of the second gate insulating layer 251 in the vertical direction, the magnitude of a voltage, e.g., the magnitude of a threshold voltage, applied to the gate structure GS1 may be less than the magnitude of a voltage applied to the second gate structure GS2. In some example embodiments, a length, e.g., a channel length, of the first gate structure GS1 may be the same as, or different from (e.g., greater than or less than) a length or channel length of the second gate structure GS2.

In some example embodiments, a top surface 244US of the first gate capping layer 244 may be coplanar with the top surface of the second gate capping layer 254US. In addition, a thickness 244th of the first gate capping layer 244 in the vertical direction may be equal to a thickness 254th of the second gate capping layer 254 in the vertical direction.

In some example embodiments, the first gate structure GS1 and the second gate structure GS2 may be formed through the same process.

The first source/drain region 261, the second source/drain region 262, and the third source/drain region 263 may be disposed in the active region ACT. Each of the first source/drain region 261, the second source/drain region 262, and the third source/drain region 263 may be an impurity-doped region.

For example, when the first and second gate structures GS1 and GS2 are PMOS transistors, the first source/drain region 261, the second source/drain region 262, and the third source/drain region 263 may be doped with p-type impurities. For another example, when the first and second gate structures GS1 and GS2 are NMOS transistors, the first source/drain region 261, the second source/drain region 262, and the third source/drain region 263 may be doped with n-type impurities. In some example embodiments, a PMOS transistor may have a light counterdoping of n-type impurities in the first and second source/drain regions 261 and 262; alternatively or additionally, an NMOS transistor may have a light counterdoping of p-type impurities in the first and second source/drain regions 261 and 262; example embodiments are not limited thereto.

The first source/drain region 261 may be interposed between the first gate structure GS1 and the second gate structure GS2.

In some example embodiments, the first source/drain region 261 may include a first region 261a, a second region 261b, and a third region 261c. The first region 261a of the first source/drain region 261 may be adjacent to the first gate structure GS1. The second region 261b of the first source/drain region 261 may be adjacent to the second gate structure GS2. The third region 261c of the first source/drain region 261 may be interposed between the first region 261a and the second region 261b.

As described herein, the expression “A is adjacent to B” may imply that A is disposed in neighborhoods with B or disposed next to and in contact with B. For example, the first region 261a of the first source/drain region 261 may be disposed in neighborhoods with the first gate structure GS1. The first region 261a of the first source/drain region 261 may be in contact with the first gate structure GS1. However, the first region 261a of the first source/drain region 261 is not in contact with the second gate structure GS2.

In addition, the second region 261b of the first source/drain region 261 may be disposed in neighborhoods with the second gate structure GS2. The second region 261b of the first source/drain region 261 may be in contact with the second gate structure GS2. However, the second region 261b of the first source/drain region 261 is not in contact with the first gate structure GS1.

In some example embodiments, the vertical level of a top surface 261a_US of the first region 261a may be higher than or above the vertical level of a top surface 261b_US of the second region 261b. For example, based on the top surface of the peripheral circuit board 200, the height of the top surface 261a_US of the first region 261a may be higher than the height of the top surface 261b_US of the second region 261b. The top surface of the third region 261c may have an inclination with respect to the top surface of the peripheral circuit board 200. However, example embodiments are not limited thereto.

In some example embodiments, a depth 261a_D of the first region 261a in the vertical direction may be equal to a depth 261b_D of the second region 261b. A depth 261a_D of the first region 261a in the vertical direction may represent the largest value among the depths of the first region 261a in the vertical direction. Likewise, a depth 261b_D of the second region 261b in the vertical direction may represent the largest value among the depths of the second region 261b in the vertical direction.

As described herein, a depth of a source/drain region may correspond to a depth at which a concentration of impurities is low or reduced to a level close to zero. In some example embodiments, the depth of the source/drain region may be determined with an analytical method such as but not limited to a secondary ion mass spectroscopy (SIMS) method; however, example embodiments are not limited thereto.

As stated above, in a semiconductor memory device according to various example embodiments, even if gate structures having gate insulating layers with different thicknesses are formed on the same active region ACT, the depth of the source/drain region can be maintained constant. Accordingly, a semiconductor memory device with improved reliability can be manufactured.

In some example embodiments, the level of the bottom surface 241BS of the first gate insulating layer 241 may be different from the level of the top surface 261a_US of the first region 261a of the first source/drain region 261. For example, the vertical level of the bottom surface 241BS of the first gate insulating layer 241 may be higher than the vertical level of the top surface 261a_US of the first region 261a. In some example embodiments, the height from the top surface of the peripheral circuit board 200 to the bottom surface 241BS of the first gate insulating layer 241 may be larger than the height of the top surface 261a_US of the first region 261a.

In a process of removing oxide layers formed on both sides of the second gate structure GS2, a part of the active region ACT adjacent to the first gate structure GS1 may be removed. Accordingly, a stepped portion may be formed between the first gate insulating layer 241 and the first source/drain region 261. Likewise, a stepped portion may be formed between the first gate insulating layer 241 and the second source/drain region 262. In this case as well, the vertical level of the bottom surface 241BS of the first gate insulating layer 241 may be higher than the vertical level of the top surface of the second source/drain region 262.

The second source/drain region 262 may be disposed at one side of the first gate structure GS1. The second source/drain region 262 and the first source/drain region 261 may be source/drain regions of the first gate structure GS1. The third source/drain region 263 may be disposed at one side of the second gate structure GS2. The third source/drain region 263 and the first source/drain region 261 may be source/drain regions of the second gate structure GS2.

A semiconductor memory device according to various example embodiments may further include a first insulating layer 230. The first insulating layer 230 may extend along the top surfaces of the first to third source/drain regions 261, 262, and 263, the profile of the first gate structure GS1, and the profile of the second gate structure GS2. The first insulating layer 230 may also be used as an etching stop layer. For example, the first insulating layer 230 may be formed of a silicon nitride layer, example embodiments are not limited thereto.

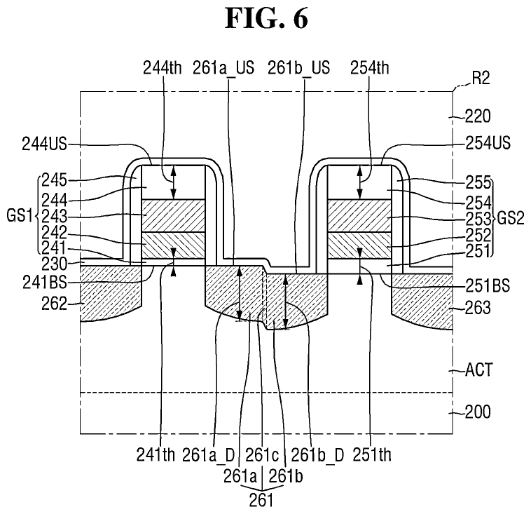

FIGS. 6 to 9 are diagrams explaining region R2 of FIG. 3 according to some example embodiments. Hereinafter, some example embodiments will be described with reference to FIGS. 6 to 9. For simplicity of description, redundant parts of the description made with reference to FIG. 5 may be recapitulated or omitted.

First, referring to FIG. 6, the level of the bottom surface 241BS of the first gate insulating layer 241 may be equal to or coplanar with the level of the top surface 261a_US of the first region 261a of the first source/drain region 261. For example, the vertical level of the bottom surface 241BS of the first gate insulating layer 241 may be equal to the vertical level of the top surface 261a_US of the first region 261a. In some example embodiments, the height from the top surface of the peripheral circuit board 200 to the bottom surface 241BS of the first gate insulating layer 241 may be equal to the height of the top surface 261a_US of the first region 261a.

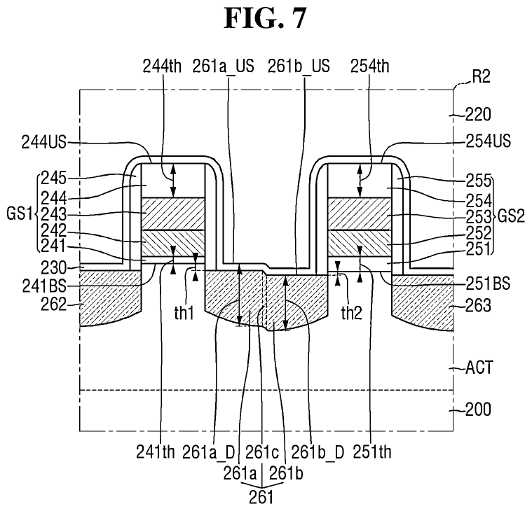

Referring to FIG. 7, the level of the bottom surface 251BS of the second gate insulating layer 251 may be different from the level of the top surface 261b_US of the second region 261b of the first source/drain region 261. For example, the vertical level of the bottom surface 251BS of the second gate insulating layer 251 may be higher than the vertical level of the top surface 261b_US of the second region 261b. In some example embodiments, the height from the top surface of the peripheral circuit board 200 to the bottom surface 251BS of the second gate insulating layer 251 may be larger than the height of the top surface 261b_US of the second region 261b.

In the process of removing the oxide layers formed on both sides of the second gate structure GS2, a part of the active region ACT adjacent to the second gate structure GS2 may be removed. As a result, a stepped portion may be formed between the second gate insulating layer 251 and the first source/drain region 261. Likewise, a stepped portion may be formed between the second gate insulating layer 251 and the third source/drain region 263. In this case as well, the vertical level of the bottom surface 251BS of the second gate insulating layer 251 may be higher than the vertical level of the top surface of the third source/drain region 263.

In FIG. 7, a first vertical distance th1 from the bottom surface 241BS of the first gate insulating layer 241 to the top surface 261a_US of the first region 261a may be different from a second vertical distance th2 from the bottom surface 251BS of the second gate insulating layer 251 to the top surface 261b_US of the second region 261b. For example, the first vertical distance th1 may be larger than the second vertical distance th2. However, the technical spirit of the present disclosure is not limited thereto.

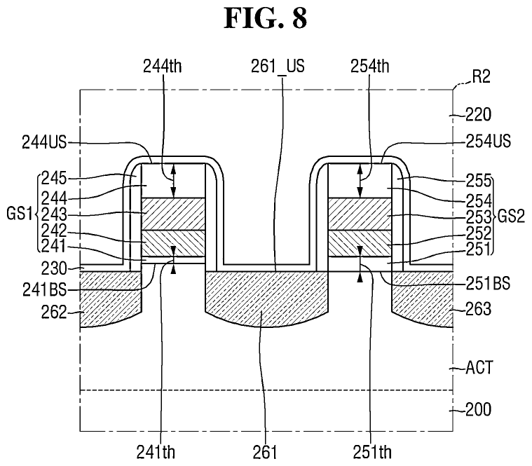

Referring to FIG. 8, the level of the top surface 261_US of the first source/drain region 261 may not change as it goes from the first gate structure GS1 toward the second gate structure GS2.

In this case, the level of the bottom surface 241BS of the first gate insulating layer 241 may be different from the level of the top surface 261_US of the first source/drain region 261. For example, the vertical level of the bottom surface 241BS of the first gate insulating layer 241 may be higher than the vertical level of the top surface 261_US of the first source/drain region 261. In other words, the height from the top surface of the peripheral circuit board 200 to the bottom surface 241BS of the first gate insulating layer 241 may be larger than the height of the top surface 261_US of the first source/drain region 261.

A stepped portion may be formed between the bottom surface 241BS of the first gate insulating layer 241 and the top surface 261_US of the first source/drain region 261. In addition, a stepped portion may be formed between the bottom surface 241BS of the first gate insulating layer 241 and the top surface of the second source/drain region 262.

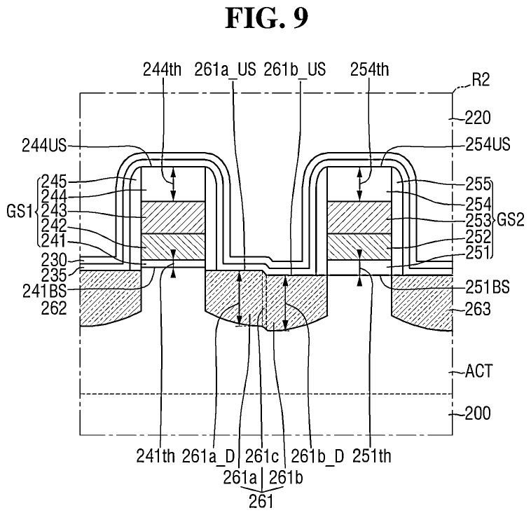

Referring to FIG. 9, a semiconductor memory device according to some example embodiments may further include a second insulating layer 235.

The second insulating layer 235 may be disposed under the first insulating layer 230. For example, the second insulating layer 235 may extend along the profile of the first gate structure GS1, the profile of the second gate structure GS2, the top surface of the first source/drain region 261, the top surface of the second source/drain region 262, and the top surface of the third source/drain region 263. The first insulating layer 230 may be disposed on the second insulating layer 235. As an example, the second insulating layer 235 may be formed of a silicon oxide layer, but the technical spirit of the present disclosure is not limited thereto.

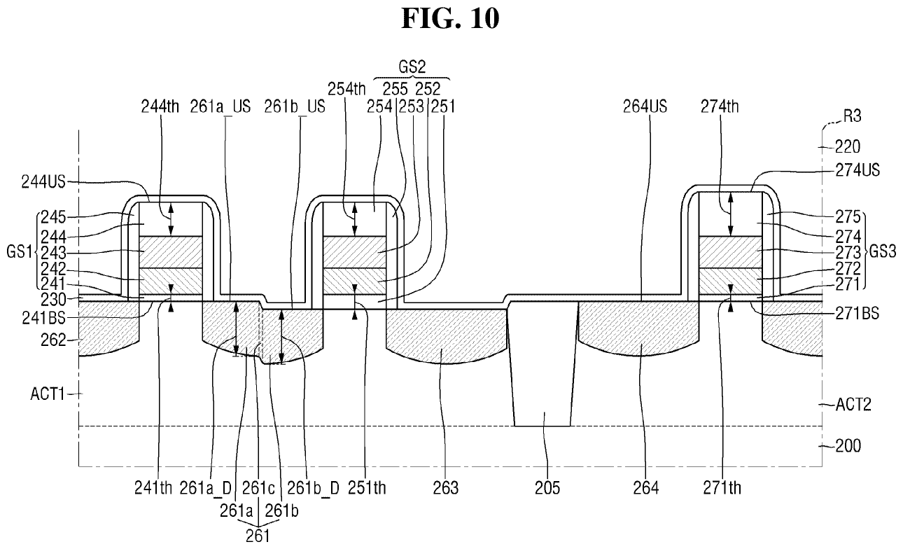

FIG. 10 is an enlarged view of region R3 of FIG. 3. For simplicity of description, redundant parts of the description made with reference to FIG. 5 may be omitted.

Referring to FIG. 10, a semiconductor memory device according to various example embodiments may include a first active region ACT1, a second active region ACT2, an element isolation layer 205, and first to third gate structures GS1, GS2, and GS3.

The element isolation layer 205 may be disposed on the peripheral circuit board 200. The element isolation layer 205 may define the first active region ACT1, and the second active region ACT2. For example, one side of the element isolation layer 205 may be the first active region ACT1 and the other side of the element isolation layer 205 may be the second active region ACT2.

The first and second gate structures GS1 and GS2 may be disposed on the first active region ACT1. The first and second gate structures GS1 and GS2 may be the same as the first and second gate structures GS1 and GS2 described with reference to FIG. 5, respectively.

The third gate structure GS3 may be disposed on the second active region ACT2. The third gate structure GS3 may intersect the second active region ACT2. The third gate structure GS3 may include a third gate insulating layer 271, a third lower gate pattern 272, a third upper gate pattern 273, a third gate capping layer 274, and a third gate spacer 275.

The third gate insulating layer 271, the third lower gate pattern 272, the third upper gate pattern 273, and the third gate capping layer 274 may be sequentially stacked on the second active region ACT2. For example, the third lower gate pattern 272 may be disposed on the third gate insulating layer 271. The third upper gate pattern 273 may be disposed on the third lower gate pattern 272. The third gate capping layer 274 may be disposed on the third upper gate pattern 273. The third gate insulating layer 271 may be in contact with at least a part of the second active region ACT2.

The third gate spacer 275 may extend along the sidewalls of the third gate insulating layer 271, the third lower gate pattern 272, the third upper gate pattern 273, and the third gate capping layer 274.

The third gate insulating layer 271 may be formed of the same material as the first gate insulating layer 241. The third lower gate pattern 272 may be formed of the same material as the first lower gate pattern 242. The third upper gate pattern 273 may be formed of the same material as the first upper gate pattern 243. The third gate capping layer 274 may be formed of the same material as the first gate capping layer 244. The third gate spacer 275 may be formed of the same material as the first gate spacer 245.

In some example embodiments, a thickness 271th of the third gate insulating layer 271 in the vertical direction may be the same as the thickness 241th of the first gate insulating layer 241 in the vertical direction. Further, the thickness 271th of the third gate insulating layer 271 in the vertical direction may be smaller than the thickness 251th of the second gate insulating layer 251 in the vertical direction. In some example embodiments, the magnitude of a voltage applied to or the absolute value of a threshold voltage of the second gate structure GS2 may be higher than the magnitude of a voltage applied to the third gate structure GS1.

In some example embodiments, the top surface of the third gate insulating layer 271 may be coplanar with the top surface of the first gate insulating layer 241 and the top surface of the second gate insulating layer 251. Further, the bottom surface 241BS of the first gate insulating layer 241 may be coplanar with a bottom surface 271BS of the third gate insulating layer 271. However, the level of the bottom surface 271BS of the third gate insulating layer 271 may be different from the level of the bottom surface 251BS of the second gate insulating layer 251. The vertical level of the bottom surface 251BS of the second gate insulating layer 251 may be lower than the vertical level of the bottom surface 271BS of the third gate insulating layer 271.

In some example embodiments, a top surface 274US of the third gate capping layer 274 may not be coplanar with the top surface 244US of the first gate capping layer 244 and the top surface 254US of the second gate capping layer 254. For example, the vertical level of the top surface 274US of the third gate capping layer 274 may be higher than the vertical level of the top surface 244US of the first gate capping layer 244 and the vertical level of the top surface 254US of the second gate capping layer 254.

In various example embodiments, with respect to the top surface of the peripheral circuit board 200, the height of the top surface 274US of the third gate capping layer 274 may be greater than the height of the top surface 244US of the first gate capping layer 244 and the height of the top surface 254US of the second gate capping layer 254. In this case, the bottom surface of the first gate capping layer 244, the bottom surface of the second gate capping layer 254, and the bottom surface of the third gate capping layer 274 may be coplanar with each other. This may be because, in the process of removing oxide layers formed on both sides of the second gate structure GS2, a part of the first gate capping layer 244 and a part of the second gate capping layer 254 are removed.

In some example embodiments, the thickness 244th of the first gate capping layer 244 in the vertical direction may be smaller than a thickness 274th of the third gate capping layer 274 in the vertical direction. The thickness 254th of the second gate capping layer 254 in the vertical direction may be smaller than the thickness 274th of the third gate capping layer 274 in the vertical direction.

In some example embodiments, a top surface 261a_US of a first region 261a of the first source/drain region 261 may be coplanar with a top surface 264US of a fourth source/drain region 264. A top surface 261b_US of a second region 261b of the first source/drain region 261 may be disposed at a lower level than the top surface 264US of the fourth source/drain region 264.

The semiconductor memory device according to some example embodiments may further include the fourth source/drain region 264. The fourth source/drain region 264 may be disposed on at least one side of the third gate structure GS3.

As illustrated, the fourth source/drain regions 264 may be disposed on both sides of the third gate structure GS3. The fourth source/drain region 264 may be a region doped with impurities. As one example, when the third gate structure GS3 is a PMOS transistor, the fourth source/drain region 264 may be doped with p-type impurities. As another example, when the third gate structure GS3 is an NMOS transistor, the fourth source/drain region 264 may be doped with n-type impurities.

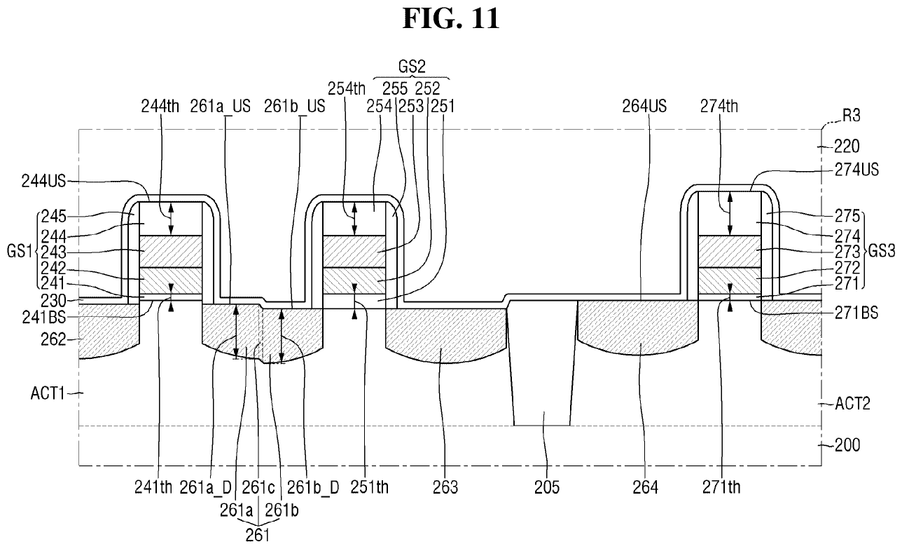

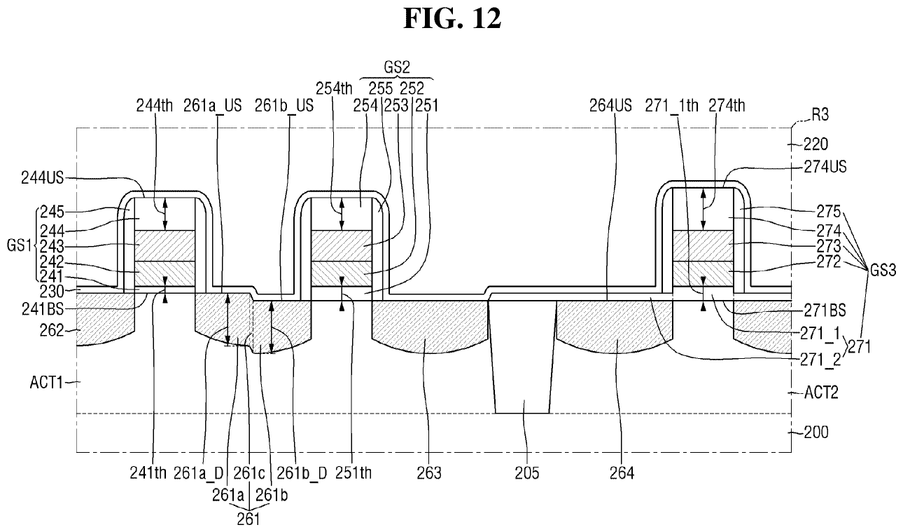

FIGS. 11 and 12 are diagrams explaining region R3 of FIG. 3 according to some other embodiments. Hereinafter, some other embodiments of the present disclosure will be described with reference to FIGS. 11 and 12. For simplicity of description, redundant parts of the description made with reference to FIG. 10 may be recapitulated or omitted.

First, referring to FIG. 11, the top surface 261a_US of the first region 261a of the first source/drain region 261 may be different from the level of the bottom surface 241BS of the first gate insulating layer 241. For example, the vertical level of the top surface 261a_US of the first region 261a may be higher than the bottom surface 241BS of the first gate insulating layer 241. In other words, with respect to the top surface of the peripheral circuit board 200, the height of the bottom surface 241BS of the first gate insulating layer 241 may be greater than the height of the top surface 261a_US of the first region 261a.

The top surface 261a_US of the first region 261a of the first source/drain region 261 may be different from the level of the top surface 264US of the fourth source/drain region 264. The vertical level of the top surface 261a_US of the first region 261a of the first source/drain region 261 may be lower than the vertical level of the top surface 264US of the fourth source/drain region 264. For example, with respect to the top surface of the peripheral circuit board 200, the height of the top surface 261a_US of the first region 261a may be smaller than the top surface 264US of the fourth source/drain region 264.

In the process of removing the oxide layers formed on both sides of the second gate structure GS2, the active region ACT adjacent to the first gate structure GS1 may be partially removed. Accordingly, a stepped portion may occur between the first gate insulating layer 241 and the first source/drain region 261. Similarly, a stepped portion may also occur between the first gate insulating layer 241 and the second source/drain region 262. In this case, the vertical level of the bottom surface 241BS of the first gate insulating layer 241 may also be higher than the vertical level of the top surface of the second source/drain region 262.

Referring to FIG. 12, a part of the third gate insulating layer 271 may extend along the top surface 264US of the fourth source/drain region 264.

For example, the third gate insulating layer 271 may include a first portion 271_1 and a second portion 271_2. The first portion 271_1 of the third gate insulating layer 271 may completely overlap the third lower gate pattern 272 in the vertical direction. The second portion 271_2 of the third gate insulating layer 271 may be a portion other than the first portion 271_1. A part of the second portion 271_2 of the third gate insulating layer 271 may extend along the top surface 264US of the fourth source/drain region 264.

The thickness 271_1th of the first portion 271_1 of the third gate insulating layer 271 in the vertical direction is greater than the thickness of the second portion 271_2 of the third gate insulating layer 271 in the vertical direction. Further, the thickness 271_1th of the first portion 271 of the third gate insulating layer 271 in the vertical direction is greater than the thickness 241th of the first gate insulating layer 241 in the vertical direction. The thickness 271_1th of the first portion 271_1 of the third gate insulating layer 271 in the vertical direction may be the same as the thickness 251th of the second gate insulating layer 251 in the vertical direction.

The second portion 271_2 of the third gate insulating layer 271 may extend along the top surface 264US of the fourth source/drain region 264. In some example embodiments, the second portion 271_2 of the third gate insulation layer 271 may extend along the top surface of the element isolation layer 205, but is not limited thereto. The second portion 271_2 of the third gate insulating layer 271 may be in contact with a part of the top surface 264US of the fourth source/drain region 264.

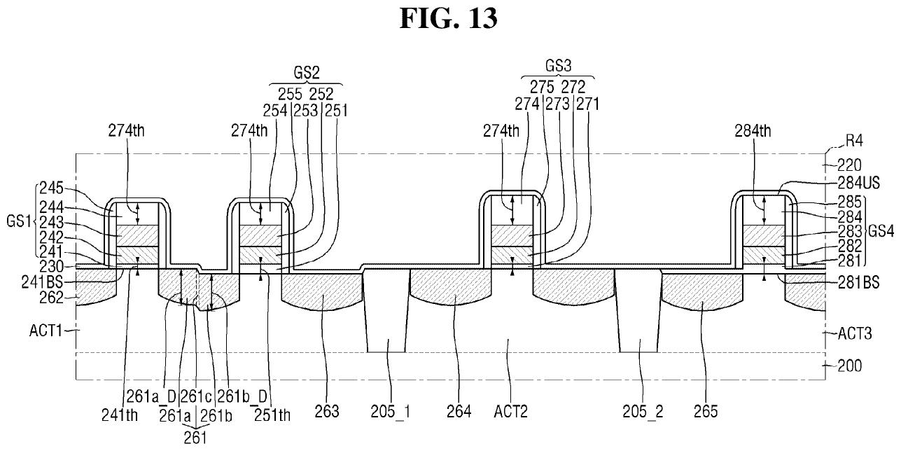

FIG. 13 is an enlarged view of region R4 of FIG. 3. For simplicity of description, redundant parts of the description made with reference to FIGS. 5 and 10 may be omitted.

Referring to FIG. 13, a semiconductor memory device according to some example embodiments may include a first element isolation layer 205_1, a second element isolation layer 205_2, first to third active regions ACT1, ACT2, and ACT3, and first to fourth gate structures GS1, GS2, GS3, and GS4.

The first to third active regions ACT1, ACT2, and ACT3 may be disposed on the peripheral circuit board 200. The first to third active regions ACT1, ACT2, and ACT3 may be defined by the first element isolation layer 205_1 and the second element isolation layer 205_2. For example, the first element isolation layer 205_1 may define the first active region ACT1 and the second active region ACT2, and the second element isolation layer 205_2 may define the second active region ACT2 and the third active region ACT3.

The first and second gate structures GS, and GS2 may be disposed on the first active region ACT1. The first and second gate structures GS1 and GS2 are the same as described with reference to FIG. 5, and thus a detailed description will be omitted.

The third gate structure GS3 may be disposed on the second active region ACT2. The third gate structure GS3 is the same as described with reference to FIG. 10, and thus a detailed description will be omitted.

The fourth gate structure GS4 may be disposed on the third active region ACT3. The fourth gate structure GS4 may intersect the third active region ACT3. The fourth gate structure GS4 may include a fourth gate insulating layer 281, a fourth lower gate pattern 282, a fourth upper gate pattern 283, a fourth gate capping layer 284, and a fourth gate spacer 285.

The fourth gate insulating layer 281, the fourth lower gate pattern 282, the fourth upper gate pattern 283, and the fourth gate capping layer 284 may be sequentially stacked on the third active region ACT3. The fourth gate insulating layer 281 may be in contact with at least a part of the third active region ACT3.

The fourth gate spacer 285 may extend along the sidewalls of the fourth gate insulating layer 281, the fourth lower gate pattern 282, the fourth upper gate pattern 283, and the fourth gate capping layer 284.

The fourth gate insulating layer 281 may be formed of the same material as the first gate insulating layer 241. The fourth lower gate pattern 282 may be formed of the same material as the first lower gate pattern 242. The fourth upper gate pattern 283 may be formed of the same material as the first upper gate pattern 243. The fourth gate capping layer 284 may be formed of the same material as the first gate capping layer 244. The fourth gate spacer 285 may be formed of the same material as the first gate spacer 245.

In various example embodiments, the fourth gate insulating layer 281 may include a first portion 281_1 and a second portion 281_2.

The first portion 281_1 of the fourth gate insulating layer 281 may completely overlap the fourth lower gate pattern 282 in the vertical direction. The second portion 281_2 of the fourth gate insulating layer 281 may be a portion other than the first portion 281_1.

A thickness 281_1th of the first portion 281_1 of the fourth gate insulating layer 281 in the vertical direction is greater than the thickness of the second portion 281_2 of the fourth gate insulating layer 281 in the vertical direction. Also, the thickness 281_1th of the first portion 281_1 of the fourth gate insulating layer 281 in the vertical direction is greater than the thickness 241th of the first gate insulating layer 241 in the vertical direction. The thickness 281_1th of the first portion 281_1 of the fourth gate insulating layer 281 in the vertical direction may be the same as the thickness 251th of the second gate insulating layer 251 in the vertical direction.

The second portion 281_2 of the fourth gate insulating layer 281 may extend along a top surface 265US of a fifth source/drain region 265. The second portion 281_2 of the fourth gate insulating layer 281 may be in contact with a part of the top surface 265US of the fifth source/drain region 265.

In some example embodiments, the top surface of the fourth gate insulating layer 281 may be coplanar with the top surface of the first gate insulating layer 241, the top surface of the second gate insulating layer 251, and the top surface of the third gate insulating layer 271.

A bottom surface 281BS of the fourth gate insulating layer 281 may be coplanar with the bottom surface 251BS of the second gate insulating layer 251. However, the level of the bottom surface 281BS of the fourth gate insulating layer 281 may be different from the level of the bottom surface 241BS of the first gate insulating layer 241 and the level of the bottom surface 271BS of the third gate insulating layer 271.

In some example embodiments, a top surface 284US of the fourth gate capping layer 284 may not be coplanar with the top surface 244US of the first gate capping layer 244 and the top surface 254US of the second gate capping layer 254. For example, the vertical level of the top surface 284US of the fourth gate capping layer 284 may be higher than or above the vertical level of the top surface 244US of the first gate capping layer 244 and the vertical level of the top surface 254US of the second gate capping layer 254. For example, with respect to the top surface of the peripheral circuit board 200, the height of the top surface 274US of the fourth gate capping layer 284 may be greater than the height of the top surface 244US of the first gate capping layer 244 and the height of the top surface 254US of the second gate capping layer 254.

In this case, the bottom surface of the first gate capping layer 244, the bottom surface of the second gate capping layer 254, and the bottom surface of the fourth gate capping layer 284 may be coplanar with each other. This may be because, in the process of removing oxide layers formed on both sides of the second gate structure GS2, a part of the first gate capping layer 244 and a part of the second gate capping layer 254 are removed.

In some example embodiments, the thickness 244th of the first gate capping layer 244 in the vertical direction may be smaller than a thickness 284th of the fourth gate capping layer 284 in the vertical direction. The thickness 254th of the second gate capping layer 254 in the vertical direction may be smaller than the thickness 284th of the fourth gate capping layer 284 in the vertical direction. However, the thickness 284th of the fourth gate capping layer 284 in the vertical direction may be the same as the thickness 274th of the third gate capping layer 274 in the vertical direction. The top surface 284US of the fourth gate capping layer 284 may be coplanar with the top surface 274US of the third gate capping layer 274.

In some example embodiments, the top surface 261b_US of the second region 261b of the first source/drain region 261 may be coplanar with the top surface 265US of the fifth source/drain region 265. The top surface 261a_US of the first region 261a of the first source/drain region 261 may be disposed at a lower level than the top surface 265US of the fifth source/drain region 265.

The semiconductor memory device according to various example embodiments may further include the fifth source/drain region 265. The fifth source/drain region 265 may be disposed on at least one side of the fourth gate structure GS4. As illustrated, the fifth source/drain regions 265 may be disposed on both sides of the fourth gate structure GS4. The fifth source/drain region 265 may be a region doped with impurities such as but not limited to the same impurities in the first and/or second source/drain region 261 and 262. As one example, when the fourth gate structure GS4 is a PMOS transistor, the fifth source/drain region 265 may be doped with p-type impurities. As another example, when the fourth gate structure GS4 is an NMOS transistor, the fifth source/drain region 265 may be doped with n-type impurities.

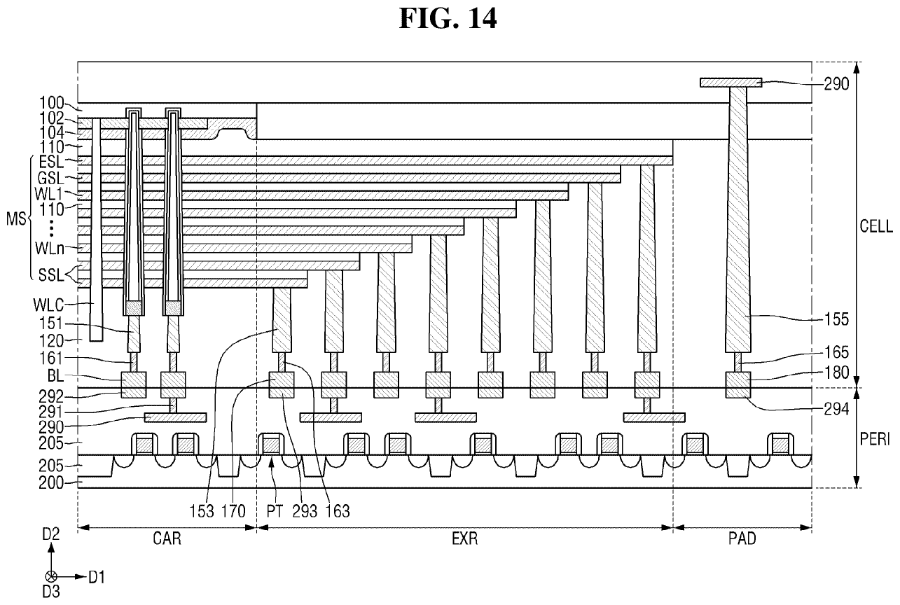

FIG. 14 is a cross-sectional view of a semiconductor memory device according to various other embodiments. Hereinafter, a semiconductor memory device according to some other embodiments will be described with reference to FIG. 14.

Referring to FIG. 14, in the semiconductor memory device according to some example embodiments, the front surface of the cell substrate 100 faces the front surface of the peripheral circuit board 200.

For example, the semiconductor memory device according to some example embodiments may have a chip to chip (C2C) structure. The C2C structure may be formed by manufacturing an upper chip including the cell structure CELL on a first wafer (e.g., the cell substrate 100), manufacturing a lower chip including the peripheral circuit structure PERI on a second wafer (e.g., the peripheral circuit board 200) different from the first wafer, and then connecting the upper chip to the lower chip by a bonding method. In some example embodiments, chips in the first wafer may be singulated and chips in the second wafer may be singulated prior to the bonding method; example embodiments are not limited thereto.

For example, the bonding method may refer to electrically connecting the bit line BL, the plurality of first metal patterns 170, and the second metal pattern 180, which are formed in the uppermost metal layer of the upper chip, to first to third bonding metals 292, 293, and 294 formed in the uppermost metal layer of the lower chip. For example, when the bit line BL, the plurality of first metal patterns 170, the second metal pattern 180, and the first to third bonding metals 292, 293, and 294 are formed of copper (Cu), the bonding method may be a Cu-Cu bonding method. However, this is only example, and the bit lines BL, the plurality of first metal patterns 170, the second metal patterns 180, and the first to third bonding metals 292, 293, and 294 may be formed of a variety of other metals, such as one or more aluminum (Al), tungsten (W) or the like.

As the bit line BL is connected to the first bonding metal 292, the plurality of first metal patterns 170 are connected to the second bonding metal 293, and the second metal pattern 180 is connected to the third bonding metal 294, the cell structure CELL may be connected to the peripheral circuit structure PERI. For example, the bit line BL, the plurality of first metal patterns 170, and the second metal pattern 180 may be electrically connected to the wiring patterns 290 via the respective first to third bonding metals 292, 293, and 294 and via contacts 291. This may allow each of the gate electrodes ECL, GSL, WL1 to WLn, and SSL and/or the source layer 102 to be electrically connected to the peripheral circuit elements PT. FIG. 14 shows the wiring pattern 290 as including one layer; however, example embodiments are not limited thereto, and the number of layers in the wiring pattern 290 may be more than one.

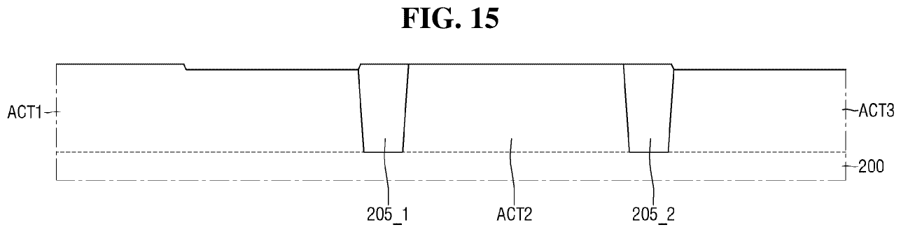

FIGS. 15 to 20 are views illustrating intermediate steps for explaining a method for fabricating a semiconductor memory device according to some example embodiments. Hereinafter, a method for fabricating a semiconductor memory device according to some example embodiments will be described with reference to FIGS. 15 to 20. For reference, FIGS. 15 to 20 may be drawings illustrating a method of manufacturing the cross section of FIG. 13.

First, referring to FIG. 15, the peripheral circuit board 200 may be provided. The first element isolation layer 205_1 and the second element isolation layer 205_2 may be formed in the peripheral circuit board 200.

The first element isolation layer 205_1 may be formed to form the first active region ACT1 and the second active region ACT2. The second element isolation layer 205_2 may be formed to form the second active region ACT2 and the third active region ACT3.

Then, a recess may be formed on one side of the first element isolation layer 205_1 in the first active region ACT1. Further, a recess may be formed on one side of the second clement isolation layer 205_2 in the third active region ACT3. The recesses may subsequently be used to form a gate insulating layer having a large thickness. The recesses may be formed by a wet etch process and/or a dry etching process; example embodiments are not limited thereto.

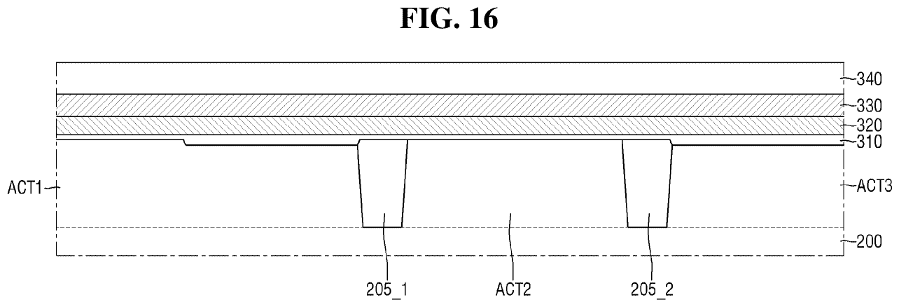

Referring to FIG. 16, a pre-gate insulating layer 310, a pre-lower gate pattern 320, a pre-upper gate pattern 330, and a pre-gate capping layer 340 may be sequentially stacked. The pre-lower gate pattern 320, the pre-upper gate pattern 330, and the pre-gate capping layer 340 may be deposited, e.g., with a chemical vapor deposition (CVD) process and/or an atomic layer deposition (ALD) process; example embodiments are not limited thereto.

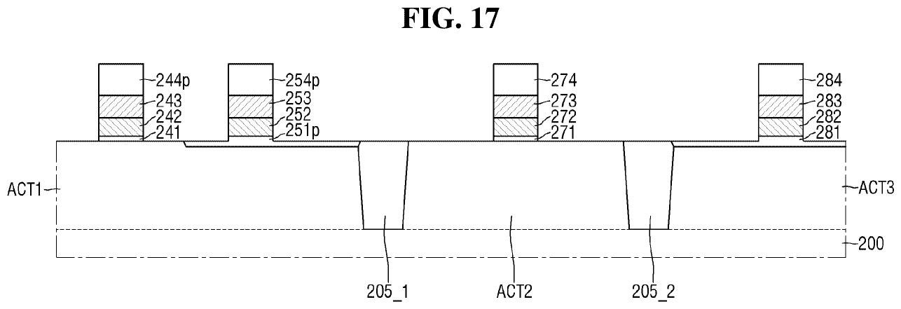

Referring to FIG. 17, the pre-gate insulating layer 310 is patterned so that the first gate insulating layer 241, a pre-second gate insulating layer 251p, the third gate insulating layer 271, and the fourth gate insulating layer 281 may be formed. The pre-lower gate pattern 320 is patterned so that the first lower gate pattern 242, the second lower gate pattern 252, the third lower gate pattern 272, and the fourth lower gate pattern 282 may be formed. The pre-upper gate pattern 330 is patterned so that the first upper gate pattern 243, the second upper gate pattern 253, the third upper gate pattern 273, and the fourth upper gate pattern 283 may be formed. Furthermore, the pre-gate capping layer 340 is patterned so that a pre-first gate capping layer 244p, a pre-second gate capping layer 254p, the third gate capping layer 274, and the fourth gate capping layer 284 may be formed.

The thickness of the first gate insulating layer 241 may be the same as the thickness of the third gate insulating layer 271. The pre-first gate capping layer 244p, the pre-second gate capping layer 254p, the third gate capping layer 274, and the fourth gate capping layer 284 may have the same thickness.

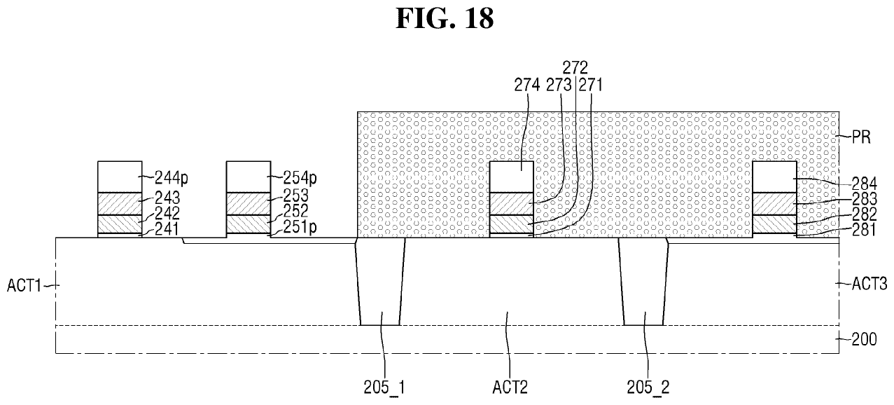

Referring to FIG. 18, a photoresist layer PR may be formed on the second active region ACT2. The photoresist layer PR may be formed of at least one of a photoresist layer, an amorphous carbon layer (ACL), a spin on hardmask (SOH), a spin on carbon (SOC), or a silicon nitride layer.

The photoresist layer PR may completely cover the third gate capping layer 274 and the fourth gate capping layer 284.

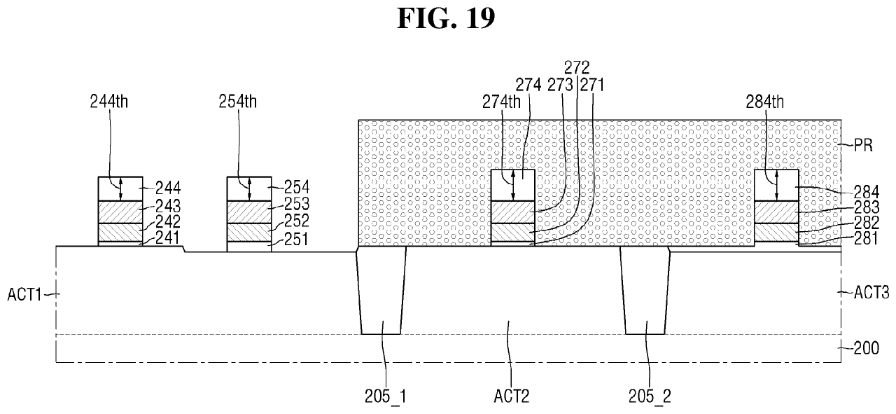

Referring to FIG. 19, the pre-second gate insulating layer 251p may be etched, e.g., with a dry etching process. The pre-second gate insulating layer 251p may be etched to form the second gate insulating layer 251. In the process of etching the pre-second gate insulating layer 251p, a part of the pre-first gate capping layer 244p and a part of the pre-second gate capping layer 254p may be removed. A part of the pre-first gate capping layer 244p and a part of the pre-second gate capping layer 254p may be removed to form the first gate capping layer 244 and the second gate capping layer 254.

Accordingly, the thickness 244th of the first gate capping layer 244 in the vertical direction and the thickness 254th of the second gate capping layer 254 in the vertical direction may be smaller than the thickness 274th of the third gate capping layer 274 in the vertical direction and the thickness 284th of the fourth gate capping layer 284 in the vertical direction, respectively.

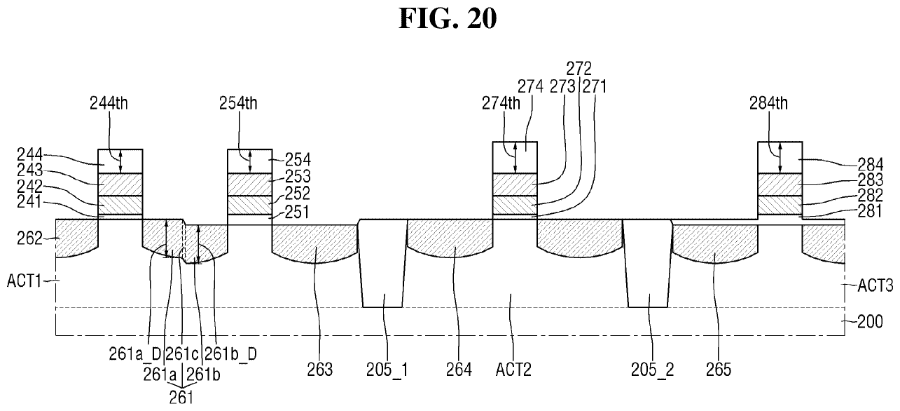

Referring to FIG. 20, the photoresist layer PR may be removed. Next, the first to fifth source/drain regions 261, 262, 263, 264, and 265 may be formed. The first to third source/drain regions 261, 262, and 263 may be formed by doping impurities, e.g., by implanting impurities, into the first active region ACT1. The fourth source/drain region 264 may be formed by doping impurities into the second active region ACT2. The fifth source/drain region 265 may be formed by doping impurities into the third active region ACT3. In some example embodiments, after doping the first to fifth source/drain regions 261, 262, 263, 264, and 265, the impurities may be activated, e.g., with an annealing process such as but not limited to a rapid thermal annealing (RTA) process.

The first source/drain region 261 may be formed between the first gate insulating layer 241 and the second gate insulating layer 251. Since the thickness of the first gate insulating layer 241 is different from the thickness of the second gate insulating layer 251, the top surface of the first source/drain region 261 may have a stepped portion. However, a depth 261a_D of the first region 261a adjacent to the first gate insulating layer 241 may be the same as a depth 261b_D of the second region 261b adjacent to the second gate insulating layer 251. Accordingly, a semiconductor memory device with improved reliability may be fabricated.

Hereinafter, an electronic system including a semiconductor memory device according to example embodiments will be described with reference to FIGS. 1 to 5 and FIGS. 21 to 23.

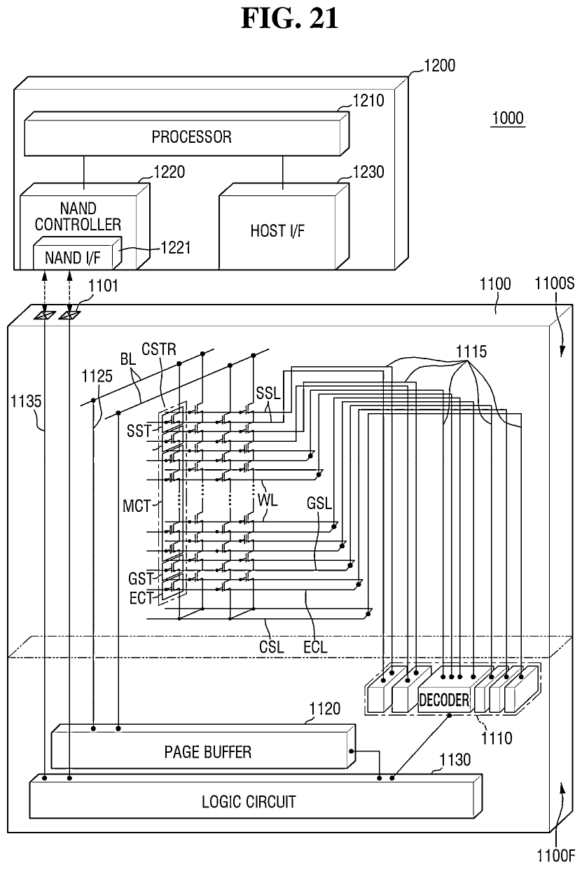

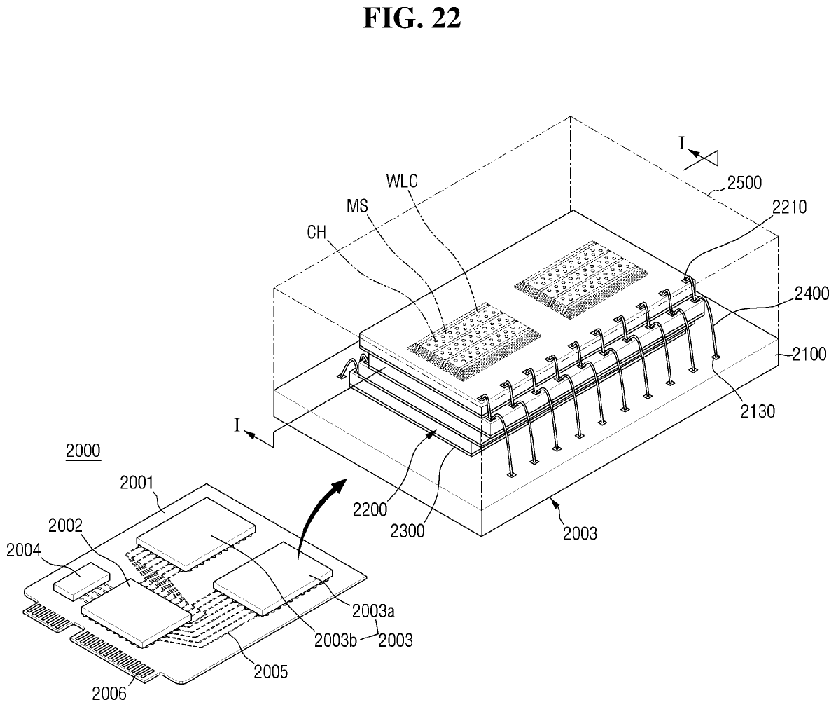

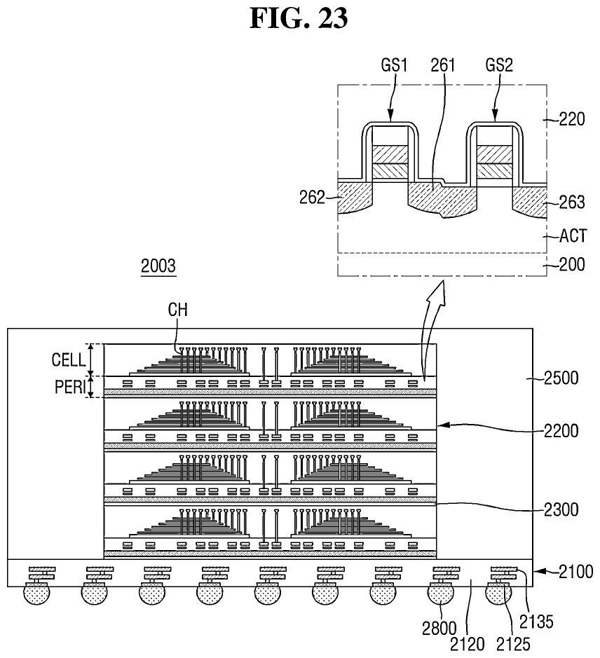

FIG. 21 is an example block diagram illustrating an electronic system according to various example embodiments. FIG. 22 is an example perspective view illustrating an electronic system according to various example embodiments. FIG. 23 is a schematic cross-sectional view taken along line I-I′ of FIG. 22.

Referring to FIG. 21, an electronic system 1000 according to some example embodiments may include a semiconductor memory device 1100 and a controller 1200 electrically connected to the semiconductor memory device 1100. The electronic system 1000 may be a storage device including one or a plurality of semiconductor memory devices 1100, or an electronic device including a storage device. For example, the electronic system 1000 may be or may include or be included in at least one of a solid state drive (SSD) device including one or a plurality of semiconductor memory devices 1100, a universal serial bus (USB), a computing system, a medical device, or a communication device.

The semiconductor memory device 1100 may be, include, or be included in, for example, a NAND flash memory device, e.g., the semiconductor memory device described with reference to FIGS. 1 to 5. The semiconductor memory device 1100 may include a first structure 1100F and a second structure 1100S on the first structure 1100F.

The first structure 1100F may be a peripheral circuit structure including a decoder circuit 1110 (e.g., the row decoder 33 in FIG. 1), a page buffer 1120 (e.g., the page buffer 35 in FIG. 1), and a logic circuit 1130 (e.g., the control logic 37 in FIG. 1).

The second structure 1100S may include the common source line CSL, the plurality of bit lines BL, and the plurality of cell strings CSTR described above with reference to FIG. 2. The cell strings CSTR may be connected to the decoder circuit 1110 via the word line WL, at least one string select line SSL, and at least one ground select line GSL. Further, the cell strings CSTR may be connected to the page buffer 1120 via the bit lines BL.

In some example embodiments, the common source line CSL and the cell strings CSTR may be electrically connected to the decoder circuit 1110 via first connection lines 1115 that extends from the first structure 1100F to the second structure 1100S.

In some example embodiments, the bit lines BL may be electrically connected to the page buffer 1120 via second connection lines 1125 that extend from the first structure 1100F to the second structure 1100S. The page buffer 1120 may be the peripheral circuit element PT described with reference to FIGS. 1 to 5.

The semiconductor memory device 1100 may communicate with the controller 1200 through an input/output pad 1101 electrically connected to the logic circuit 1130 (e.g., the control logic 37 in FIG. 1). The input/output pad 1101 may be electrically connected to the logic circuit 1130 through an input/output connection wiring 1135 extending from the first structure 1100F to the second structure 1100S.

The controller 1200 may include a processor 1210, a NAND controller 1220, and a host interface 1230. In some example embodiments, the electronic system 1000 may include the plurality of semiconductor memory devices 1100. In this case, the controller 1200 may control the plurality of semiconductor memory devices 1100.

The processor 1210 may control the overall operation of the electronic system 1000 including the controller 1200. The processor 1210 may operate according to a predetermined firmware, and may access the semiconductor memory device 1100 by controlling the NAND controller 1220. The NAND controller 1220 may include a NAND interface 1221 that communicates with the semiconductor memory device 1100. A control command for controlling the semiconductor memory device 1100, data to be written to the memory cell transistors MCT of the semiconductor memory device 1100, data to be read from the memory cell transistors MCT of the semiconductor memory device 1100, and the like may be transmitted through the NAND interface 1221. The host interface 1230 may provide a communication function between the electronic system 1000 and an external host. When the control command is received from the external host through the host interface 1230, the processor 1210 may control the semiconductor memory device 1100 in response to the control command.

Referring to FIGS. 21 to 23, an electronic system according to some example embodiments may include a main substrate 2001, a main controller 2002 mounted on the main substrate 2001, one or more semiconductor packages 2003, and a DRAM 2004. The semiconductor package 2003 and the DRAM 2004 may be connected to the main controller 2002 by wiring patterns 2005 formed on the main substrate 2001.

The main substrate 2001 may include a connector 2006 having a plurality of pins connected to the external host. In the connector 2006, the number and arrangement of the pins may vary depending on a communication interface between the electronic system 2000 and the external host. In various example embodiments, the electronic system 2000 may communicate with the external host through any one of interfaces such as one or more of universal serial bus (USB), peripheral component interconnect express (PCIe), serial advanced technology attachment (SATA), and M-PHY for universal flash storage (UFS). In some example embodiments, the electronic system 2000 may be operated by a power supplied from the external host through the connector 2006. The electronic system 2000 may further include a power management integrated circuit (PMIC) that distributes the power supplied from the external host to the main controller 2002 and the semiconductor package 2003.

The main controller 2002 may write or read data to/from the semiconductor package 2003, and may improve the operation speed of the electronic system 2000.

The DRAM 2004 may be a buffer memory for reducing a speed difference between the external host and the semiconductor package 2003 as a data storage space. The DRAM 2004 included in the electronic system 2000 may also operate as a sort of cache memory, and may also provide a space for temporarily storing data in controlling the semiconductor package 2003. When the electronic system 2000 includes the DRAM 2004, the main controller 2002 may include not only a NAND controller for controlling the semiconductor package 2003 but also a DRAM controller for controlling the DRAM 2004.

The semiconductor package 2003 may include a first semiconductor package 2003a and a second semiconductor package 2003b spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, the semiconductor chips 2200 on the package substrate 2100, adhesive layers 2300 respectively disposed on the bottom surfaces of the semiconductor chips 2200, connection structures 2400 electrically connecting the semiconductor chips 2200 to the package substrate 2100, and a molding layer 2500 covering the semiconductor chips 2200 and the connection structures 2400 above the package substrate 2100.

The package substrate 2100 may be a printed circuit board including upper package pads 2130. Each of the semiconductor chips 2200 may include an input/output pad 2210. The input/output pad 2210 may correspond to the input/output pad 1101 of FIG. 21.

In various example embodiments, the connection structure 2400 may be a bonding wire that electrically connects the input/output pad 2210 to the upper package pads 2130. Accordingly, in each of first semiconductor package 2003a and the second semiconductor package 2003b, the semiconductor chips 2200 may be electrically connected to each other, and may be electrically connected to the upper package pads 2130 of the package substrate 2100, by a wire bonding method. In some example embodiments, in each of the first semiconductor package 2003a and the second semiconductor package 2003b, the semiconductor chips 2200 may be electrically connected to each other by a connection structure including a through silicon via (TSV) instead of the wire bonding type connection structure 2400.

In various example embodiments, the main controller 2002 and the semiconductor chips 2200 may be included in one package. In some example embodiments, the main controller 2002 and the semiconductor chips 2200 may be mounted on a separate interposer substrate different from the main substrate 2001, and the main controller 2002 may be connected to the semiconductor chips 2200 by wirings formed on the interposer substrate.

In some example embodiments, the package substrate 2100 may be or may include or be included in a printed circuit board. The package substrate 2100 may include a package substrate body portion 2120, the upper package pads 2130 disposed on the top surface of the package substrate body portion 2120, lower pads 2125 arranged on the bottom surface of the package substrate body portion 2120 or exposed through the bottom surface thereof, and internal wirings 2135 electrically connecting the upper pads 2130 to the lower pads 2125 in the package substrate body portion 2120. The upper pads 2130 may be electrically connected to the connection structures 2400. The lower pads 2125 may be connected to the wiring patterns 2005 of the main substrate 2001 of the electronic system 2000 through conductive connectors 2800, as shown in FIG. 21.

Referring to FIGS. 22 and 23, in the electronic system according to some example embodiments, each of the semiconductor chips 2200 may include the semiconductor memory device described above with reference to FIGS. 1 to 5. For example, each of the semiconductor chips 2200 may include the peripheral circuit structure PERI and the cell structure CELL stacked on the peripheral circuit structure PERI. For example, the peripheral circuit structure PERI may include the peripheral circuit board 200 and the peripheral circuit element PT described above with reference to FIGS. 3 to 5. Further, for example, the cell structure CELL may include the cell substrate 100, the mold structure MS, the channel structure CH, the word line cutting structure WLC, and the bit line BL as described above with reference to FIGS. 3 to 5.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

In concluding the detailed description, those of ordinary skill in the art will appreciate that many variations and modifications may be made to the preferred embodiments without substantially departing from the principles of the present disclosure. Therefore, the disclosed example embodiments of the disclosure are used in a generic and descriptive sense only and not for purposes of limitation. Additionally example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a cell structure; and
a peripheral circuit structure electrically connected to the cell structure,
wherein the cell structure comprises,
a plurality of gate electrodes extending in a first direction and spaced apart in a second direction,
a channel structure penetrating the plurality of gate electrodes in the second direction, and
a bit line connected to the channel structure and extending in a third direction, and
the peripheral circuit structure comprises,
an active region,
a first gate structure comprising a first gate insulating layer intersecting the active region and in contact with the active region,
a second gate structure comprising a second gate insulating layer spaced apart from the first gate structure, and in contact with the active region, and
a source/drain region in the active region and between the first gate structure and the second gate structure, wherein
a thickness of the first gate insulating layer is less than a thickness of the second gate insulating layer,
the source/drain region comprises a first region adjacent to the first gate structure and a second region adjacent to the second gate structure, and
a depth of the first region is equal to a depth of the second region.

2. The semiconductor memory device of claim 1, wherein
the first gate structure comprises a first gate capping layer on the first gate insulating layer,
the second gate structure comprises a second gate capping layer on the second gate insulating layer, and
a top surface of the second gate capping layer is coplanar with a top surface of the first gate capping layer.

3. The semiconductor memory device of claim 2, wherein a thickness of the first gate capping layer is equal to a thickness of the second gate capping layer.

4. The semiconductor memory device of claim 1, wherein the second gate insulating layer is not on the second region of the source/drain region.

5. The semiconductor memory device of claim 1, wherein a bottom surface of the first gate insulating layer is above a top surface of the first region of the source/drain region.

6. The semiconductor memory device of claim 1, wherein a bottom surface of the second gate insulating layer is coplanar with or above a top surface of the second region of the source/drain region.

7. The semiconductor memory device of claim 1, wherein the source/drain region is connected to the bit line of the cell structure.

8. The semiconductor memory device of claim 1, wherein a top surface of the first region is above a level of a top surface of the second region.

9. A semiconductor memory device comprising:
first and second active regions that are defined by an element isolation layer;
a first gate structure comprising a first gate insulating layer intersecting the first active region, and in contact with the first active region;
a second gate structure comprising a second gate insulating layer extending parallel to the first gate structure, and in contact with the first active region; and
a first source/drain region in the first active region and between the first gate structure and the second gate structure;
a third gate structure comprising a third gate insulating layer intersecting the second active region, and in contact with the second active region; and
a second source/drain region in the second active region and on at least one side of the third gate structure, wherein
a thickness of the first gate insulating layer is less than a thickness of the second gate insulating layer,
the first source/drain region comprises a first region adjacent to the first gate structure and a second region adjacent to the second gate structure,
a depth of the first region is equal to a depth of the second region, and
wherein a top surface of the first region is below a top surface of the second source/drain region.

10. The semiconductor memory device of claim 9, wherein the thickness of the second gate insulating layer is greater than the thickness of the third gate insulating layer.

11. The semiconductor memory device of claim 9, wherein each of the first and second source/drain regions is connected to a same or a different bit line of a cell structure.

12. The semiconductor memory device of claim 9, wherein the second gate insulating layer is not on the second region of the first source/drain region.

13. The semiconductor memory device of claim 9, wherein
the first gate structure comprises a first gate capping layer on the first gate insulating layer,
the second gate structure comprises a second gate capping layer on the second gate insulating layer, and
a top surface of the second gate capping layer is coplanar with a top surface of the first gate capping layer.

14. The semiconductor memory device of claim 13, wherein
the third gate structure comprises a third gate capping layer on the third gate insulating layer, and
a top surface of the third gate capping layer is below a top surface of the first gate capping layer.

15. The semiconductor memory device of claim 14, wherein the thickness of the third gate capping layer is less than the thickness of the first gate capping layer.

16. The semiconductor memory device of claim 9, wherein a top surface of the first region is coplanar with or above a top surface of the second region.

17. The semiconductor memory device of claim 9, wherein a bottom surface of the first gate insulating layer is above the top surface of the first region of the first source/drain region.

18. A semiconductor memory device comprising:
a cell structure; and
a peripheral circuit structure electrically connected to the cell structure,
wherein the cell structure comprises
a plurality of gate electrodes extending in a first direction, and spaced apart in a second direction,
a channel structure penetrating the plurality of gate electrodes in the second direction, and
a bit line connected to the channel structure, and extending in a third direction, and
the peripheral circuit structure comprises,
first and second active regions that are defined by an element isolation layer;
a first gate structure comprising a first gate insulating layer intersecting the first active region, and in contact with the first active region;
a second gate structure comprising a second gate insulating layer extending parallel to the first gate structure, and in contact with the first active region;
a first source/drain region in the first active region and between the first gate structure and the second gate structure;
a third gate structure comprising a third gate insulating layer intersecting the second active region, and in contact with the second active region; and
a second source/drain region in the second active region and on at least one side of the third gate structure, wherein
a thickness of the first gate insulating layer is less than a thickness of the second gate insulating layer,
the first source/drain region comprises a first region adjacent to the first gate structure, and a second region adjacent to the second gate structure,
a top surface of the first region is above a top surface of the second region, but below a top surface of the second source/drain region, and
a depth of the first region is equal to a depth of the second region.

19. The semiconductor memory device of claim 18, wherein
the first gate structure comprises a first gate capping layer on the first gate insulating layer,
the second gate structure comprises a second gate capping layer on the second gate insulating layer,
the third gate structure comprises a third gate capping layer on the third gate insulating layer,
a top surface of the second gate capping layer is coplanar with a top surface of the first gate capping layer, and
a top surface of the third gate capping layer is below the top surface of the first gate capping layer.

20. The semiconductor memory device of claim 19, wherein a thickness of the third gate capping layer is less than a thickness of the first gate capping layer.
